(19) United States
(12) Patent Application Publication
(10) Pub. No.: US 2025/0392326 A1
(43) Pub. Date: Dec. 25, 2025

(54) System and Method for Cross-Stream Asymmetric Enhancement with Multi-Objective Optimization

(71) Applicant: AtomBeam Technologies Inc., Moraga, CA (US)

(72) Inventors: Joshua Cooper, Columbia, SC (US); Grant Fickes, Columbia, SC (US); Charles Yeomans, Orinda, CA (US)

(21) Appl. No.: 19/313,170

(22) Filed: Aug. 28, 2025

Related U.S. Application Data
(63) Continuation-in-part of application No. 18/491,754, filed on Oct. 21, 2023, now Pat. No. 12,407,364.
Application No. 18/491,754 is a continuation-in-part of application No. 18/190,044, filed on Mar. 24, 2023, now Pat. No. 11,831,343.
Application No. 18/190,044 is a continuation-in-part of application No. 17/875,201, filed on Jul. 27, 2022, now Pat. No. 11,700,013.
Application No. 17/875,201 is a continuation of application No. 17/514,913, filed on Oct. 29, 2021, now Pat. No. 11,424,760.
Application No. 17/514,913 is a continuation-in-part of application No. 17/404,699, filed on Aug. 17, 2021, now Pat. No. 11,385,794.

(51) Int. Cl. H03M 7/30; G06N 20/00

(52) U.S. Cl. CPC H03M 7/3059; G06N 20/00; H03M 7/6005

(57) ABSTRACT

A system and method for cross-stream asymmetric enhancement combines machine learning-driven asymmetric codebook generation with dyadic distribution algorithms to enable simultaneous optimization of compression efficiency, cryptographic security, and error correction capability. The system analyzes input data characteristics and initializes multiple specialized ML models to generate stream-specific asymmetric codebooks optimized for different objectives. Enhanced dyadic distribution processing creates three pre-conditioned data streams that are processed through parallel asymmetric transformation pipelines: compression-optimized for maximum data reduction, security-optimized for cryptographic strength, and error-correction-optimized for robust recovery capability. Cross-stream optimization coordinates the multiple processing paths to ensure overall system coherence while maintaining individual stream objectives. The system supports multiple operating modes including ultra-high compression using only the primary stream, broadcast quality using primary and secondary streams, and archival mode using all streams for lossless reconstruction. The system supports graduated access control that enables different reconstruction quality levels based on available stream combinations.

### CROSS-REFERENCE TO RELATED APPLICATIONS

Priority is claimed in the application data sheet to the following patents or patent applications, each of which is expressly incorporated herein by reference in its entirety:
Ser. No. 18/491,754
Ser. No. 18/190,044
Ser. No. 17/875,201
Ser. No. 17/514,913
Ser. No. 17/404,699
Ser. No. 63/388,411
Ser. No. 17/727,913
Ser. No. 19/307,725
Ser. No. 19/011,509
Ser. No. 18/515,272

### BACKGROUND OF THE INVENTION

### Field of the Invention

The present invention is in the field of data compression and encryption, and in particular to systems and methods that integrate asymmetric codebook generation with dyadic distribution-based algorithms to achieve simultaneous multi-objective optimization.

### Discussion of the State of the Art

Current encryption methodologies including AES, RSA, and elliptic curve cryptography operate independently of compression algorithms, necessitating complex multi-stage processing pipelines where data must be compressed, encrypted, transmitted, then decrypted and decompressed at the destination. Each stage introduces latency, computational overhead, and potential security vulnerabilities, while the sequential approach prevents optimization across the entire processing pipeline.

Error correction systems such as Reed-Solomon codes and LDPC codes are designed as independent solutions that add 10% to 50% redundancy overhead without consideration for compression efficiency or security requirements. This separation prevents intelligent redundancy distribution that could enhance error recovery while minimizing overhead and maintaining security properties.

Asymmetric codebook systems provide advantages by enabling different transformation behaviors at encoding and decoding stages, allowing enhanced security through codebook asymmetry and novel applications such as data transformation and graduated access control.

Dyadic distribution-based compression and encryption systems leverage mathematical properties of dyadic probability distributions to achieve optimal Huffman coding while providing cryptographic benefits. These systems can achieve superior compression ratios compared to traditional algorithms while inherently providing encryption capabilities, eliminating the need for separate encryption stages. However, existing dyadic distribution systems are optimized for single-objective performance and do not provide mechanisms for balancing multiple competing objectives or adapting to different application requirements.

The fundamental limitation of existing approaches is their inability to simultaneously optimize multiple competing objectives while maintaining system coherence and efficiency. Current systems require practitioners to choose between compression efficiency, security strength, and error correction capability, or accept suboptimal performance in all areas when addressing multiple objectives through sequential processing stages. This limitation becomes particularly problematic in applications such as medical imaging, financial data transmission, video streaming, and secure communications where all three objectives are critical.

Furthermore, existing systems lack adaptive capabilities that enable continuous improvement based on operational experience and changing requirements. Static optimization approaches become increasingly ineffective as data characteristics evolve, security threats advance, and application requirements change over time. The absence of learning and adaptation capabilities means that systems must be manually reconfigured or replaced to maintain optimal performance.

Current approaches to multi-stream processing typically involve simple data splitting or redundancy techniques that do not optimize each stream for specific objectives. Existing multi-stream systems may duplicate data across multiple channels for reliability or split data into arbitrary segments for parallel processing, but they do not implement stream-specific optimization that tailors each stream's characteristics to achieve optimal performance for designated purposes.

What is needed is an integrated system and method that combines asymmetric codebook generation with dyadic distribution-based algorithms and machine learning optimization to achieve simultaneous multi-objective optimization across compression efficiency, cryptographic security, and error correction capability. Such a system should provide stream-specific processing architectures that enable optimal performance for each objective while maintaining overall system coherence, implement adaptive learning capabilities that enable continuous improvement, and support graduated access control and partial reconstruction capabilities that meet the requirements of modern collaborative and security-conscious applications.

### SUMMARY OF THE INVENTION

Accordingly, the inventor has conceived and reduced to practice, a system and method for cross-stream asymmetric enhancement combines machine learning-driven asymmetric codebook generation with dyadic distribution algorithms to enable simultaneous optimization of compression efficiency, cryptographic security, and error correction capability. The system analyzes input data characteristics and initializes multiple specialized ML models to generate stream-specific asymmetric codebooks optimized for different objectives. Enhanced dyadic distribution processing creates three pre-conditioned data streams that are processed through parallel asymmetric transformation pipelines: compression-optimized for maximum data reduction, security-optimized for cryptographic strength, and error-correction-optimized for robust recovery capability. Cross-stream optimization coordinates the multiple processing paths to ensure overall system coherence while maintaining individual stream objectives. The system supports multiple operating modes including ultra-high compression using only the primary stream, broadcast quality using primary and secondary streams, and archival mode using all streams for lossless reconstruction. The system supports graduated access control that enables different reconstruction quality levels based on available stream combinations.

According to a preferred embodiment, a system for cross-stream asymmetric enhancement with multi-objective optimization is disclosed, comprising: a computing device comprising a processor and a memory; a plurality of programming instructions stored in the memory which, when operating on the processor, cause the computing device to: analyze input data to determine processing requirements for multiple objectives comprising compression efficiency, cryptographic security, and error correction capability; generate a plurality of asymmetric codebooks using machine learning algorithms, wherein each asymmetric codebook is optimized for a different objective and produces different output transformations when applied to the same input data; apply dyadic distribution processing to the input data to create multiple data streams, wherein each data stream is pre-conditioned for optimal processing by a corresponding asymmetric codebook; process the multiple data streams using the plurality of asymmetric codebooks to simultaneously optimize the multiple objectives; and generate output data according to a selected combination of the processed data streams, wherein different stream combinations provide different levels of reconstruction capability.

According to another preferred embodiment, a method for cross-stream asymmetric enhancement with multi-objective optimization is disclosed, comprising the steps of: analyzing input data to determine processing requirements for multiple objectives comprising compression efficiency, cryptographic security, and error correction capability; generating a plurality of asymmetric codebooks using machine learning algorithms, wherein each asymmetric codebook is optimized for a different objective and produces different output transformations when applied to the same input data; applying dyadic distribution processing to the input data to create multiple data streams, wherein each data stream is pre-conditioned for optimal processing by a corresponding asymmetric codebook; processing the multiple data streams using the plurality of asymmetric codebooks to simultaneously optimize the multiple objectives; and generating output data according to a selected combination of the processed data streams, wherein different stream combinations provide different levels of reconstruction capability.

According to a further aspect, the method includes generating the plurality of asymmetric codebooks comprising generating a compression-optimized codebook that maximizes data reduction, a security-optimized codebook that maximizes cryptographic strength, and an error-correction-optimized codebook that maximizes error detection and correction capability.

According to a further aspect, the method includes applying dyadic distribution processing comprising transforming probability distributions of the input data to optimize compatibility with subsequent asymmetric codebook processing.

According to a further aspect, the method includes machine learning algorithms comprising neural networks trained using multi-objective optimization techniques that balance competing performance criteria across the multiple objectives.

According to a further aspect, the method includes generating output data comprising selecting an ultra-high compression mode using a single stream, a broadcast quality mode using two streams, or an archival mode using three streams.

According to a further aspect, the method includes the steps of monitoring performance metrics from the processed data streams and adaptively updating the plurality of asymmetric codebooks based on the performance metrics.

According to a further aspect, the method includes each asymmetric codebook comprising transformation matrices that are mathematically optimized for its corresponding objective while maintaining reconstruction capability for authorized users.

According to a further aspect, the method includes the step of coordinating processing across the multiple data streams to ensure that optimization of one objective does not compromise performance of other objectives.

According to a further aspect, the method includes different levels of reconstruction capability enabling graduated access control where different users can access different quality levels of reconstructed data based on available stream combinations.

According to a further aspect, the method includes the step of applying additional security measures comprising stream interleaving and temporal encryption to the output data.

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary, and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment of the invention.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is a block diagram illustrating an exemplary system architecture for combining data compression with encryption using split-stream processing.

FIG. 19 is a block diagram illustrating an exemplary system architecture for decompressing and decrypting incoming data that was processed using split-stream processing.

FIG. 20 is a block diagram illustrating an exemplary system architecture for data compression and decompression using asymmetric codebooks.

FIG. 21 is a flow diagram illustrating an exemplary method for generating and distributing asymmetric codebooks.

FIG. 22A is a flow diagram illustrating an exemplary method for using asymmetric codebooks to provide data mapping at a reconstruction engine.

FIG. 22B is a flow diagram illustrating an exemplary method for using asymmetric codebooks to facilitate data encryption.

FIG. 23 is a block diagram illustrating an exemplary system architecture for a dyadic distribution-based compression and encryption platform, according to an embodiment.

FIG. 24 is a block diagram illustrating another exemplary system architecture for a dyadic distribution-based compression and encryption platform, according to an embodiment.

FIG. 25 is a flow diagram illustrating an exemplary method for implementing a dyadic distribution algorithm, according to an aspect.

FIG. 26 is a flow diagram illustrating an exemplary method for providing lossless, dyadic distribution-based compression and encryption, according to an aspect.

FIG. 27 is a block diagram illustrating an exemplary system architecture for a cross-stream asymmetric enhancement system that combines various compression techniques with dyadic distribution-based encryption and stream-specific asymmetric codebook processing, according to an embodiment.

FIG. 28 is a block diagram illustrating an exemplary aspect of the cross-stream asymmetric system, an ML codebook generator cluster, according to an embodiment.

FIG. 29 is a block diagram illustrating an exemplary aspect of the cross-stream asymmetric system, an enhanced dyadic distribution engine that implements one or more dyadic distribution algorithms specifically optimized for multi-stream processing and asymmetric codebook compatibility.

FIG. 30 is a flow diagram illustrating an exemplary method for cross-stream asymmetric enhancement processing that combines dyadic distribution algorithms with stream-specific asymmetric codebook transformations to achieve simultaneous compression, encryption, and error correction optimization, according to an embodiment.

FIG. 31 is a flow diagram illustrating an exemplary method for multi-stream reconstruction that processes compressed and encrypted data streams generated by the cross-stream asymmetric enhancement system to reconstruct original data with varying levels of quality based on available stream combinations, according to an embodiment.

FIG. 32 illustrates an exemplary computing environment on which an embodiment described herein may be implemented.

### DETAILED DESCRIPTION OF THE INVENTION

The inventor has conceived, and reduced to practice, a system and method for cross-stream asymmetric enhancement combines machine learning-driven asymmetric codebook generation with dyadic distribution algorithms to enable simultaneous optimization of compression efficiency, cryptographic security, and error correction capability.

In one embodiment, the system and method comprise a form of asymmetric encoding/decoding wherein original data is encoded by an encoder according to a codebook and sent to a decoder, but instead of just decoding the data according to the codebook to reconstruct the original data, data manipulation rules such as mapping, transformation, encryption, are applied at the decoding stage to transform the decoded data into a different data set from the original data. This provides a form of double security, in that the intended final data set is never transferred and can't be obtained even if the codebook is known. It can only be obtained if the codebook and the series of data manipulations after decoding are known.

In another embodiment, encoding and decoding can be performed on a distributed computing network by incorporating a behavior appendix into the codebook, such that the encoder and/or decoder at each node of the network comply with network behavioral rules, limits, and policies. This embodiment is useful because it allows for independent, self-contained enforcement of network rules, limits, and policies at each node of the network within the encoding/decoding system itself, and not through the use of an enforcement mechanism external to the encoding/decoding system. This provides a higher level of security because the enforcement occurs before the data is encoded or decoded. For example, if rule appended to the codebook states that certain sourceblocks are associated with malware and are not to be encoded or decoded, the data cannot be encoded to be transmitted within the network or decoded to be utilized within the network, regardless of external enforcement mechanisms (e.g., anti-virus software, network software that enforces network policies, etc.).

In some embodiments, the data compaction system may be configured to encode and decode genomic data. There are many applications in biology and genomics in which large amounts of DNA or RNA sequencing data must to be searched to identify the presence of a pattern of nucleic acid sequences, or oligonucleotides. These applications include, but are not limited to, searching for genetic disorders or abnormalities, drug design, vaccine design, and primer design for Polymerase Chain Reaction (PCR) tests or sequencing reactions.

These applications are relevant across all species, humans, animals, bacteria, and viruses. All of these applications operate within large datasets; the human genome for example, is very large (3.2 billion base pairs). These studies are typically done across many samples, such that proper confidence can be achieved on the results of these studies. So, the problem is both wide and deep, and requires modern technologies beyond the capabilities of traditional or standard compression techniques. Current methods of compressing data are useful for storage, but the compressed data cannot be searched until it is decompressed, which poses a big challenge for any research with respect to time and resources.

The compaction algorithms described herein not only compress data as well as, or better than, standard compression technologies, but more importantly, have major advantages that are key to much more efficient applications in genomics. First, some configurations of the systems and method described herein allow random access to compacted data without unpacking them first. The ability to access and search within compacted datasets is a major benefit and allows for utilization of data for searching and identifying sequence patterns without the time, expense, and computing resources required to unpack the data. Additionally, for some applications certain regions of the genomic data must be searched, and certain configurations of the systems and methods allow the search to be narrowed down even within compacted data. This provides an enormous opportunity for genomic researchers and makes mining genomics datasets much more practical and efficient.

In some embodiments, data compaction may be combined with data serialization to maximize compaction and data transfer with extremely low latency and no loss. For example, a wrapper or connector may be constructed using certain serialization protocols (e.g., BeBop, Google Protocol Buffers, MessagePack). The idea is to use known, deterministic file structure (schemes, grammars, etc.) to reduce data size first via token abbreviation and serialization, and then to use the data compaction methods described herein to take advantage of stochastic/statistical structure by training it on the output of serialization. The encoding process can be summarized as: serialization-encode->compact-encode, and the decoding process would be the reverse: compact-decode->serialization-decode. The deterministic file structure could be automatically discovered or encoded by the user manually as a scheme/grammar. Another benefit of serialization in addition to those listed above is deeper obfuscation of data, further hardening the cryptographic benefits of encoding using codebooks.

In some embodiments, the data compaction systems and methods described herein may be used as a form of encryption. As a codebook created on a particular data set is unique (or effectively unique) to that data set, compaction of data using a particular codebook acts as a form of encryption as that particular codebook is required to unpack the data into the original data. As described previously, the compacted data contains none of the original data, just codeword references to the codebook with which it was compacted. This inherent encryption avoids entirely the multiple stages of encryption and decryption that occur in current computing systems, for example, data is encrypted using a first encryption algorithm (say, AES-256) when stored to disk at a source, decrypted using AES-256 when read from disk at the source, encrypted using TLS prior to transmission over a network, decrypted using TLS upon receipt at the destination, and re-encrypted using a possibly different algorithm (say, TwoFish) when stored to disk at the destination.

In some embodiments, an encoding/decoding system as described herein may be incorporated into computer monitors, televisions, and other displays, such that the information appearing on the display is encoded right up until the moment it is displayed on the screen. One application of this configuration is encoding/decoding of video data for computer gaming and other applications where low-latency video is required. This configuration would take advantage of the typically limited information used to describe scenery/imagery in low-latency video software applications, such an in gaming, AR/VR, avatar-based chat, etc. The encoding would benefit from there being a particularly small number of textures, emojis, AR/VR objects, orientations, etc., which can occur in the user interface (UI), at any point along the rendering pipeline where this could be helpful.

In some embodiments, the data compaction systems and methods described herein may be used to manage high volumes of data produced in robotics and industrial automation. Many AI based industrial automation and robotics applications collect a large amount of data from each machine, particularly from cameras or other sensors. Based upon the data collected, decisions are made as to whether the process is under control or the parts that have been manufactured are in spec. The process is very high speed, so the decisions are usually made locally at the machine based on an AI inference engine that has been previously trained. The collected data is sent back to a data center to be archived and for the AI model to be refined.

In many of these applications, the amount of data that is being created is extremely large. The high production rate of these machines means that most factory networks cannot transmit this data back to the data center in anything approaching real time. In fact, if these machines are operating close to 24 hours a day, 7 days a week, then the factory networks can never catch up and the entirety of the data cannot be sent. Companies either do data selection or use some type of compression requiring expensive processing power at each machine to reduce the amount of data that needs to be sent. However, this either loads down the processors of the machine, or requires the loss of certain data in order to reduce the required throughput.

The data encoding/decoding systems and methods described herein can be used in some configurations to solve this problem, as they represent a lightweight, low-latency, and lossless solution that significantly reduces the amount of data to be transmitted. Certain configurations of the system could be placed on each machine and at the server/data center, taking up minimal memory and processing power and allowing for all data to be transmitted back to the data center. This would enable audits whenever deeper analysis needs to be performed as, for example, when there is a quality problem. It also ensures that the data centers, where the AI models are trained and retrained, have access to all of the up-to-date data from all the machines.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

The term “bit” refers to the smallest unit of information that can be stored or transmitted. It is in the form of a binary digit (either 0 or 1). In terms of hardware, the bit is represented as an electrical signal that is either off (representing 0) or on (representing 1).

The term “byte” refers to a series of bits exactly eight bits in length.

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless”, in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio”, and as used herein all mean the size of the original data relative to the size of the compressed data (e.g., if the new data is 70% of the size of the original, then the deflation/compression ratio is 70% or 0.7.)

The term “data” means information in any computer-readable form.

The term “data set” refers to a grouping of data for a particular purpose. One example of a data set might be a word processing file containing text and formatting information.

The term “effective compression” or “effective compression ratio” refers to the additional amount data that can be stored using the method herein described versus conventional data storage methods. Although the method herein described is not data compression, per se, expressing the additional capacity in terms of compression is a useful comparison.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code to a sourceblock in the library plus an indication of that sourceblock's location in a particular data set.

### Conceptual Architecture

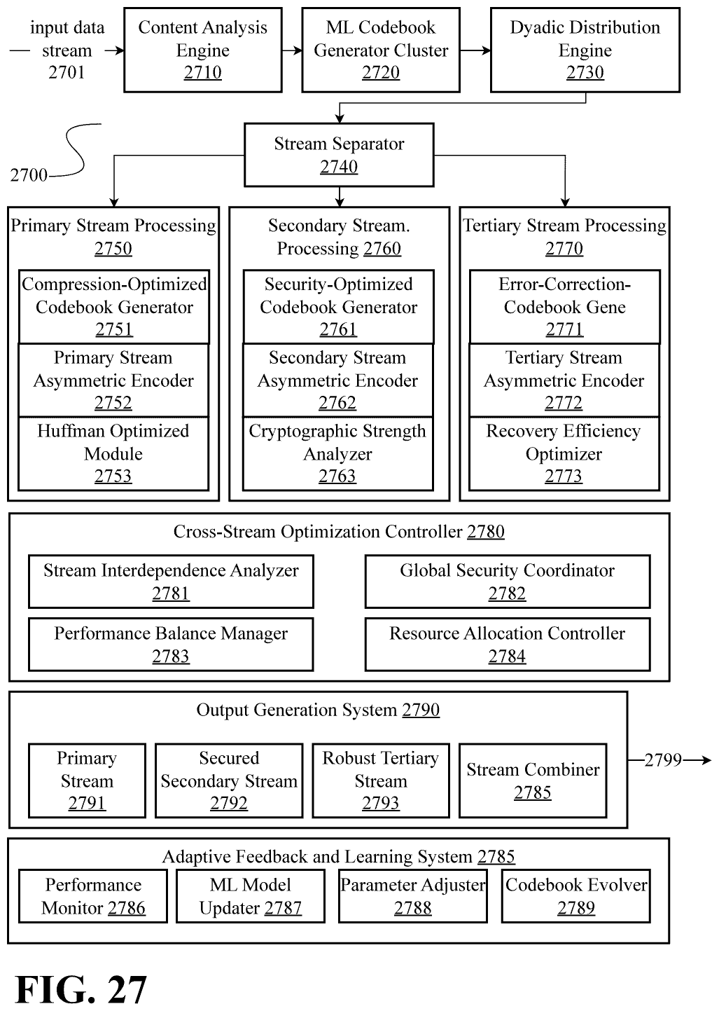

FIG. 27 is a block diagram illustrating an exemplary system architecture for a cross-stream asymmetric enhancement system 2700 that combines various compression techniques with dyadic distribution-based encryption and stream-specific asymmetric codebook processing, according to an embodiment. The system 2700 represents a novel integration of multiple data processing paradigms to enable enhanced compression ratios, multi-layered security, and adaptive optimization capabilities for data transmission and storage applications.

According to the embodiment, the system receives, retrieves, or otherwise obtains an input data stream 2701 which is received by a content analysis engine 2710. The content analysis engine 2710 comprises specialized components configured to analyze the characteristics of the incoming data to determine optimal processing parameters for subsequent stages. Content analysis engine 2710 evaluates data complexity, sensitivity requirements, compression potential, and security needs, providing foundational information that guides the selection of processing strategies and optimization targets for the entire system pipeline.

The analyzed data can be then passed to an ML codebook generator cluster 2720, which comprises multiple machine learning models specifically trained to generate asymmetric codebooks optimized for different processing objectives. ML codebook generator cluster 2720 utilizes the analysis results from content analysis engine 2710 to initialize and configure stream-specific machine learning models, each designed to produce codebooks that optimize particular aspects of data processing such as compression efficiency, cryptographic strength, or error correction capability.

The processed data flows to a dyadic distribution engine 2730, which implements dyadic distribution algorithms to transform the input data into probability distributions optimized for both compression and encryption. For example, medical images, financial data, video content, and text documents each receive optimized dyadic transformations tailored to their specific statistical properties. Dyadic distribution engine 2730 operates in conjunction with the ML codebook generator cluster 2720 to ensure that the dyadic transformations are pre-conditioned to work optimally with the subsequent asymmetric processing stages. The dyadic transformation process inherently provides cryptographic benefits because the transformation process introduces controlled randomness while maintaining statistical properties. The original data cannot be reconstructed without knowledge of both the transformation matrix and the specific random choices made during transformation. This creates an initial layer of encryption that is then enhanced by the subsequent asymmetric processing. The dyadic transformation obfuscates the original data patterns while maintaining complete reversibility for authorized users who possess the transformation parameters. This obfuscation is cryptographically significant because it eliminates statistical patterns that could be exploited by attackers. The output from dyadic distribution engine 2730 can be processed by a stream separator 2740, which divides the dyadic-processed data into three distinct streams, each optimized for different processing objectives and security requirements. The engine receives feedback from downstream processing components about the effectiveness of its transformations and uses this information to refine its algorithms and improve future performance.

For data destined for the primary stream, the engine creates dyadic distributions that are specifically optimized for subsequent compression-focused asymmetric transformations. This may comprise analyzing what types of probability patterns will enable the compression-optimized codebooks to achieve maximum efficiency. For data destined for the secondary stream, the engine creates dyadic distributions that enhance the effectiveness of security-focused asymmetric transformations. This may comprise introducing controlled entropy patterns that will enable better cryptographic randomization while maintaining reconstruction capability. For data destined for the tertiary stream, the engine creates dyadic distributions that optimize for error-correction-focused asymmetric transformations, potentially creating patterns that will enable more effective redundancy distribution and error detection.

The system 2700 incorporates a plurality of parallel stream-specific processing pipelines, each comprising specialized components designed to optimize particular aspects of data handling. Primary stream processing 2750 focuses on compression optimization and comprises compression-optimized codebook generator 2751, primary stream asymmetric encoder 2752, and Huffman optimization module 2753. Compression-optimized codebook generator 2751 generates asymmetric codebooks specifically designed to maximize compression ratios while maintaining reconstruction fidelity. Primary stream asymmetric encoder 2752 applies the generated codebooks to transform the primary stream data into representations that are optimized for subsequent compression algorithms. Huffman optimization module 2753 ensures that the asymmetrically transformed data achieves optimal performance when processed through Huffman coding or similar entropy coding techniques.

Secondary stream processing 2760 concentrates on security optimization and comprises security-optimized codebook generator 2761, secondary stream asymmetric encoder 2762, and cryptographic strength analyzer 2763. Security-optimized codebook generator 2761 creates asymmetric codebooks designed to maximize cryptographic strength and resistance to various attack vectors while preserving the information necessary for authorized reconstruction. Secondary stream asymmetric encoder 2762 applies security-focused transformations to the secondary stream data, introducing controlled randomness and cryptographic obfuscation while maintaining functional relationships required for system operation. Cryptographic strength analyzer 2763 continuously monitors and validates the security properties of the transformed secondary stream, ensuring that the output maintains desired cryptographic characteristics and resistance to analysis.

Tertiary stream processing 2770 emphasizes error correction and recovery optimization and comprises error-correction-optimized codebook generator 2771, tertiary stream asymmetric encoder 2772, and recovery efficiency optimizer 2773. Error-correction-optimized codebook generator 2771 generates asymmetric codebooks specifically designed to enhance error detection and correction capabilities while minimizing redundancy overhead. Tertiary stream asymmetric encoder 2772 transforms the tertiary stream data to create self-healing data structures that can maintain integrity and enable recovery even under adverse conditions. Recovery efficiency optimizer 2773 analyzes and optimizes the error correction characteristics of the transformed tertiary stream, ensuring maximum recovery capability with minimal additional data overhead.

Cross-stream optimization controller 2780 manages the coordination and optimization of processing across all three streams to ensure optimal overall system performance. Cross-stream optimization controller 2780 comprises several specialized components that work together to balance competing objectives and maintain system coherence. Stream interdependency analyzer 2781 examines the relationships and dependencies between the three streams, identifying opportunities for optimization and ensuring that modifications to one stream do not adversely affect the others. Global security coordinator 2782 manages security policies and requirements across all streams, ensuring that the overall system maintains desired security properties while optimizing individual stream characteristics. Performance balance manager 2783 continuously monitors system performance metrics and adjusts processing parameters to maintain optimal balance between compression efficiency, security strength, and processing speed. Resource allocation controller 2784 manages computational and memory resources across the plurality of processing pipelines, dynamically adjusting resource distribution based on current processing loads and performance requirements.

The three processed streams are output as enhanced primary stream 2791, secured secondary stream 2792, and robust tertiary stream 2793. Enhanced primary stream 2791 represents the compression-optimized output that provides maximum data reduction while maintaining essential information for reconstruction. Secured secondary stream 2792 contains transformation and security information that has been processed to maximize cryptographic protection while preserving the metadata necessary for enhanced reconstruction. Robust tertiary stream 2793 comprises error correction and recovery data that has been optimized for maximum fault tolerance and recovery capability.

Stream combiner 2795 receives the three enhanced output streams and combines them according to configurable policies and application requirements to produce final output stream 2799. Stream combiner 2795 may implement various combination strategies, including, but not limited to, selective stream inclusion based on application requirements, interleaving techniques that optimize transmission characteristics, or encryption and authentication protocols that protect the integrity of the combined output. Final output stream 2799 represents the complete processed data that incorporates the benefits of compression optimization, security enhancement, and error correction optimization in a single integrated output suitable for transmission or storage.

The system 2700 incorporates an adaptive feedback and learning system 2785 that enables continuous improvement and optimization of system performance. Adaptive feedback and learning system 2785 comprises performance monitor 2786, ML model updater 2787, parameter adjuster 2788, and codebook evolver 2789. Performance monitor 2786 continuously tracks system performance metrics including, but not limited to, compression ratios, processing speed, security effectiveness, and error correction capability, providing real-time feedback on system operation. ML model updater 2787 uses the performance feedback to update and refine the machine learning models used in the codebook generation process, enabling the system to adapt to changing data characteristics and requirements. Parameter adjuster 2788 modifies processing parameters throughout the system based on performance feedback and changing conditions, ensuring optimal operation under varying circumstances. Codebook evolver 2789 may be configured to implement evolutionary algorithms and continuous learning techniques to improve codebook generation over time, enabling the system to develop increasingly effective asymmetric transformations as it processes more data.

The system 2700 provides several significant advantages over conventional data processing approaches. The combination of dyadic distribution processing with stream-specific asymmetric codebook transformation enables simultaneous optimization of multiple objectives that are typically considered mutually exclusive. The multi-stream architecture allows for graduated access control and partial reconstruction capabilities, enabling applications that require different levels of data access for different users or applications. The adaptive learning capabilities ensure that system performance continues to improve over time as the machine learning models adapt to encountered data patterns and processing requirements. The cross-stream optimization ensures that improvements in one processing arca do not compromise performance in others, maintaining overall system effectiveness while enabling specialized optimization of individual components.

According to an implementation of an embodiment, one or more machine learning training algorithms employed in system 2700 may utilize a multi-objective optimization framework that simultaneously optimizes compression efficiency, cryptographic strength, and error correction capability while maintaining asymmetric codebook properties. In some aspects, the training system utilizes an adaptive multi-objective codebook training (AMOCT) algorithm that initializes compression codebook parameters, security codebook parameters, and error correction codebook parameters, along with objective weighting factors for each set of parameters. For each training iteration, the algorithm can sample a training batch from the input data distribution, generate candidate codebooks for each stream, and evaluate a multi-objective loss function comprising compression loss, security loss, recovery loss, and coherence loss components. The parameters can be updated using gradient descent with momentum, asymmetric constraint enforcement is applied, and objective weights are updated based on performance feedback to ensure optimal balance between competing objectives.

According to an embodiment, a compression-optimized codebook training algorithm implemented in compression-optimized codebook generator 2751 employs an entropy-aware compression training (EACT) approach that focuses on maximizing data reduction while preserving reconstruction fidelity. In various embodiments, the training process may utilize a neural network architecture specifically designed for codebook generation, comprising an encoder-decoder structure with attention mechanisms that learn optimal symbol-to-symbol mappings for compression purposes. The algorithm may further incorporate a Huffman-predictive loss function that estimates the effectiveness of Huffman coding on asymmetrically transformed data before actually applying the coding, enabling end-to-end optimization for downstream compression algorithms. The loss function may be configured to incorporate reconstruction loss to ensure the asymmetric transformation preserves essential information, entropy loss to encourage probability distributions optimized for Huffman coding, and compression efficiency loss that directly measures data size reduction achieved by the transformation. In some aspects, the training process may utilize adaptive learning rates that adjust based on convergence characteristics of different loss components, with early training emphasizing reconstruction loss and later stages focusing on entropy optimization and compression efficiency through curriculum learning that gradually increases training example complexity.

According to an aspect of an embodiment, a security-optimized codebook training algorithm implemented in security-optimized codebook generator 2761 employs an adversarial cryptographic training (ACT) approach that utilizes adversarial training techniques combined with cryptographic analysis to generate codebooks that maximize security while preserving necessary functionality. The training architecture may employ a generator-discriminator framework where the generator creates asymmetric codebooks and multiple specialized discriminators attempt to extract information from transformed output using different attack vectors including, but not limited to, statistical analysis, pattern recognition, and frequency analysis attacks. The generator network can be trained to fool all discriminators simultaneously while maintaining asymmetric properties that enable authorized reconstruction, with the loss function incorporating cryptographic metrics such as avalanche effect, correlation coefficient, and entropy measures. The algorithm may be configured to employ progressive adversarial hardening, where the strength and sophistication of adversarial attacks increase throughout training to create codebooks resistant to a wide range of attack strategies and capable of adapting to emerging threats. The security loss function can combine adversarial loss, entropy loss, avalanche effect measurement, and correlation analysis to ensure transformed data exhibits high-quality encryption properties.

According to an embodiment, an error-correction-optimized codebook training algorithm implemented in error-correction-optimized codebook generator 2771 can employ a redundancy-aware error correction training (RAECT) approach that focuses on creating codebooks that enhance error detectability and correctability while minimizing redundancy overhead. The training process can utilize simulated error injection to teach the codebook generator how to create transformations robust against various types of data corruption, incorporating different error models including, but not limited to, random bit flips, burst errors, and systematic failures to ensure comprehensive error resistance. The algorithm employs adaptive redundancy distribution that learns to dynamically distribute error correction information based on the importance and vulnerability of different data segments, providing enhanced protection for critical information while minimizing overall overhead. The loss function balances error correction capability against redundancy overhead, encouraging transformations that provide maximum error resilience with minimal additional data by incorporating error detection capability loss, error correction capability loss, redundancy overhead penalty, and reconstruction efficiency loss components.

According to an aspect of an embodiment, cross-stream optimization controller 2780 implements a cross-stream coherence training (CSCT) algorithm that ensures the three (or more) stream-specific codebooks work together effectively and that improvements in one stream do not compromise performance in others. The coordination training process operates at a higher level than individual stream training algorithms, optimizing interactions and dependencies between the three codebook generators using multi-agent reinforcement learning techniques where each stream-specific generator acts as an agent that must cooperate with others to achieve optimal overall system performance. The coordination loss function measures reconstruction quality when using different stream combinations, security effectiveness of the combined system, and overall compression efficiency of the integrated approach, encouraging specialization within each stream while maintaining overall system coherence. The algorithm can be configured to employ dynamic weight adaptation that automatically adjusts the relative importance of different objectives based on current performance and application requirements, allowing the system to adapt to changing priorities without requiring manual retuning.

According to an aspect, the adaptive feedback and learning system 2785 implements a continuous adaptive training (CAT) algorithm that operates alongside the main processing pipeline, collecting performance data and gradually updating trained models based on observed results. The algorithm may comprise techniques from online learning and transfer learning to adapt to new data characteristics without forgetting previously learned capabilities, using a combination of gradient-based updates for fine-tuning and evolutionary algorithms for more substantial structural changes. The system maintains multiple model versions and employs A/B testing techniques to validate improvements before deploying them to the main processing pipeline, implementing, for instance, performance-guided model selection that maintains an ensemble of models for each stream and dynamically selects the best-performing combination based on current data characteristics and performance requirements. The training algorithms may employ sophisticated data management and augmentation techniques including, but not limited to, synthetic data generation using generative adversarial networks (GANs) trained on similar data distributions, adversarial example generation to improve robustness, cross-domain transfer learning to generalize across data types, and progressive difficulty curriculum that gradually increases training complexity to ensure robust performance across diverse data types and conditions.

### Exemplary Use Case: Secure Medical Imaging and Telemedicine System

A large hospital network requires a system to securely transmit high-resolution medical imaging data (CT scans, MRIs, X-rays) between multiple facilities while enabling different levels of access for various healthcare professionals. The system must simultaneously achieve maximum compression for bandwidth efficiency, maintain strict security compliance with Health Insurance Portability and Accountability Act (HIPAA) regulations, and ensure data integrity for accurate medical diagnosis. Traditional approaches require separate compression and encryption stages, resulting in computational overhead, security vulnerabilities, and suboptimal performance.

The hospital network implements system 2700 to process medical imaging data through the cross-stream asymmetric enhancement architecture. Input data stream 2701 receives a high-resolution MRI scan (approximately 500 MB) containing both diagnostic imagery and patient metadata. Content analysis engine 2710 analyzes the medical data and identifies three distinct data categories: primary diagnostic imagery requiring maximum compression, patient identification and medical history requiring maximum security protection, and scan parameters and metadata requiring robust error correction for regulatory compliance.

ML codebook generator cluster 2720 initializes three specialized machine learning models trained specifically for medical imaging applications. The compression model has been trained on thousands of medical images to understand anatomical structures and optimize compression of diagnostic regions while preserving critical details. The security model has been trained to protect patient privacy information according to healthcare regulations and industry best practices. The error correction model has been trained to ensure perfect reconstruction of medical metadata and scan parameters that are critical for accurate diagnosis and regulatory compliance.

Dyadic distribution engine 2730 processes the analyzed medical data and applies probability distribution transformations that optimize the data for subsequent stream-specific processing. The engine recognizes that diagnostic imagery contains predictable anatomical patterns suitable for aggressive compression, patient information requires cryptographic randomization for privacy protection, and technical metadata needs redundant encoding for error resilience. Stream separator 2740 divides the processed data into three distinct streams: diagnostic image data, patient privacy data, and technical metadata.

Primary stream processing 2750 handles the diagnostic imagery through compression-optimized codebook generator 2751, which creates asymmetric transformations specifically designed for medical image compression. The generator has learned to preserve diagnostically relevant features such as tissue boundaries, lesion characteristics, and contrast variations while aggressively compressing background regions and non-diagnostic areas. Primary stream asymmetric encoder 2752 applies these medical-specific transformations, achieving improved compression ratios while maintaining diagnostic quality equivalent to the original images. Huffman optimization module 2753 further enhances compression by optimizing entropy coding for the medical image patterns, resulting in a greater final compression ratio than that achieved by traditional medical imaging compression standards.

Secondary stream processing 2760 manages patient privacy and identification data through security-optimized codebook generator 2761, which creates asymmetric transformations that render patient information cryptographically secure while preserving the ability for authorized healthcare providers to access necessary information. Secondary stream asymmetric encoder 2762 applies security transformations that exceed HIPAA encryption requirements, providing multiple layers of protection including patient name obfuscation, medical record number encryption, and demographic data scrambling. Cryptographic strength analyzer 2763 validates that the transformed data achieves cryptographic randomness equivalent to AES-256 encryption while maintaining 50% less computational overhead than traditional encryption approaches.

Tertiary stream processing 2770 handles scan parameters, technical metadata, and regulatory compliance information through error-correction-optimized codebook generator 2771. This component creates asymmetric transformations that embed comprehensive error detection and correction capabilities specifically designed for medical applications where data integrity is critical for patient safety. Tertiary stream asymmetric encoder 2772 applies transformations that enable detection and correction of data corruption, significantly exceeding industry standards for medical data transmission. Recovery efficiency optimizer 2773 ensures that even if transmission errors occur, the system can reconstruct complete and accurate technical metadata necessary for proper image interpretation and regulatory compliance.

Cross-stream optimization controller 2780 coordinates the three processing streams to achieve optimal overall system performance for the medical imaging application. Stream interdependency analyzer 2781 recognizes that diagnostic image quality must be preserved even if compression is reduced, patient privacy protection cannot be compromised regardless of performance impacts, and technical metadata integrity is non-negotiable for regulatory compliance. Global security coordinator 2782 ensures that the combined system meets all healthcare security requirements while optimizing performance, implementing policies that prevent any processing optimization from reducing security below regulatory minimums.

Performance balance manager 2783 continuously monitors the medical imaging workflow and adjusts processing parameters based on clinical priorities. During emergency situations, the system automatically prioritizes rapid transmission over maximum compression, while during routine operations, it optimizes for bandwidth efficiency and storage cost reduction. Resource allocation controller 2784 manages computational resources across the hospital network, dynamically distributing processing load between local servers and cloud resources based on current clinical demand and network conditions.

Adaptive feedback and learning system 2785 continuously improves system performance based on clinical usage patterns and diagnostic outcomes. Performance monitor 2786 tracks diagnostic accuracy, transmission reliability, and clinical workflow efficiency, providing feedback to optimize system parameters for medical applications. ML model updater 2787 refines compression algorithms based on diagnostic feedback from radiologists, ensuring that compression optimizations never compromise diagnostic capability.

Parameter adjuster 2788 automatically adapts processing parameters based on clinical priorities and network conditions. During night shifts when network traffic is low, the system optimizes for maximum compression and storage efficiency, while during peak clinical hours, it prioritizes rapid transmission and immediate availability. Codebook evolver 2789 develops increasingly sophisticated transformations based on the specific medical imaging patterns encountered, creating hospital-specific optimizations that exceed generic compression approaches.

The graduated access control enabled by stream-specific processing addresses a critical need in healthcare environments where different professionals require different levels of data access. Traditional approaches provide binary access control that either grants complete access or no access, creating workflow inefficiencies and security risks. The stream-specific approach enables role-based access that improves both security and operational efficiency.

The adaptive learning capabilities ensure that system performance continues to improve based on actual clinical usage, creating increasingly effective medical-specific optimizations that generic systems cannot achieve. This results in a system that becomes more valuable over time rather than requiring periodic replacement or major upgrades, providing significant long-term cost advantages for healthcare organizations.

This exemplary use case demonstrates how the cross-stream asymmetric enhancement system addresses real-world requirements that cannot be effectively met by traditional approaches, providing quantifiable benefits in compression efficiency, security protection, data integrity, and operational effectiveness while enabling new capabilities such as graduated access control and adaptive optimization that enhance the overall value proposition for complex, security-sensitive applications.

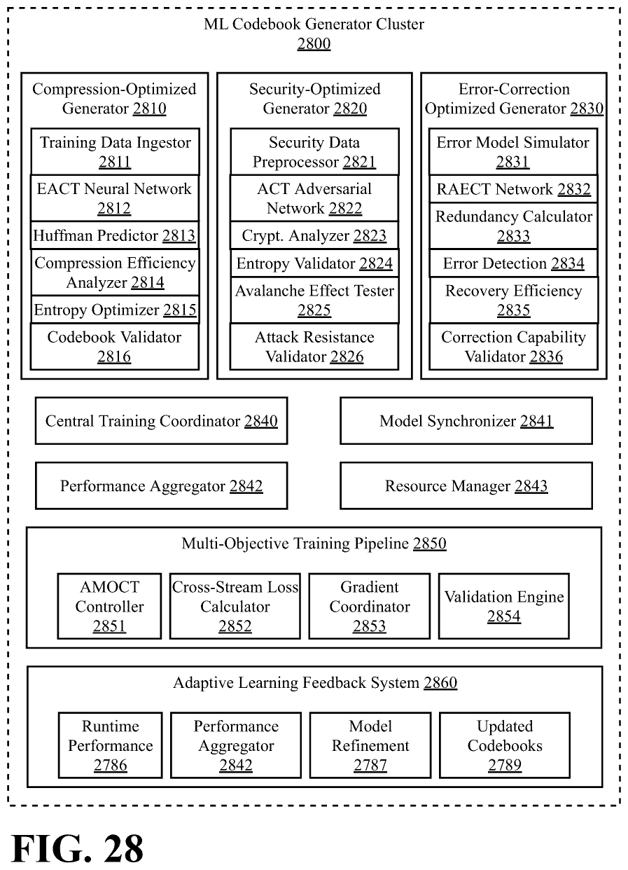

FIG. 28 is a block diagram illustrating an exemplary aspect of the cross-stream asymmetric system, an ML codebook generator cluster, according to an embodiment. According to the embodiment, ML codebook generator cluster 2800 comprises multiple specialized generator subsystems, each configured to optimize codebooks for specific stream processing requirements. A compression-optimized generator 2810 is specifically designed to create asymmetric codebooks that maximize data compression efficiency while preserving reconstruction fidelity for primary stream processing. Compression-optimized generator 2810 comprises a training data ingestor 2811, which receives and preprocesses training data specifically selected for compression optimization objectives. An EACT neural network 2812 implements the entropy-aware compression training algorithm using a specialized neural network architecture comprising encoder-decoder structures with attention mechanisms that learn optimal symbol-to-symbol mappings for compression purposes. A Huffman predictor 2813 estimates the effectiveness of Huffman coding on asymmetrically transformed data before actually applying the coding, enabling end-to-end optimization for downstream compression algorithms. A compression efficiency analyzer 2814 measures and evaluates the data size reduction achieved by generated transformations, providing feedback for optimization of compression performance. An entropy optimizer 2815 encourages probability distributions optimized for Huffman coding by adjusting transformation parameters to achieve target entropy characteristics. A codebook validator 2816 verifies the mathematical properties and functional correctness of generated compression-optimized codebooks before deployment to ensure reliable operation.

A security-optimized generator 2820 creates asymmetric codebooks designed to maximize cryptographic strength and resistance to various attack vectors while preserving information necessary for authorized reconstruction. Security-optimized generator 2820 comprises a security data preprocessor 2821 that receives and conditions training data specifically for security optimization, including sanitization and anonymization procedures to prevent security vulnerabilities during training. An ACT adversarial network 2822 implements the adversarial cryptographic training algorithm using a generator-discriminator framework where multiple specialized discriminators attempt to extract information from transformed output using different attack vectors including, but not limited to, statistical analysis, pattern recognition, and frequency analysis attacks. A cryptographic analyzer 2823 evaluates the cryptographic properties of generated transformations using established metrics such as avalanche effect, correlation coefficients, and entropy measures to ensure transformed data exhibits properties of high-quality encryption. An entropy validator 2824 confirms that security transformations achieve desired entropy characteristics and cryptographic randomness equivalent to established encryption standards. An avalanche effect tester 2825 measures the degree to which small changes in input data result in significant changes in output data, validating a fundamental property of strong cryptographic transformations. An attack resistance validator 2826 tests generated codebooks against various attack methodologies to ensure they maintain security properties under adversarial conditions.

An error-correction-optimized generator 2830 focuses on creating asymmetric codebooks that enhance error detectability and correctability while minimizing redundancy overhead for tertiary stream processing. Error-correction-optimized generator 2830 comprises an error model simulator 2831 that generates realistic error patterns including, but not limited to, random bit flips, burst errors, and systematic failures to train the codebook generator for comprehensive error resistance. A RAECT network 2832 implements the redundancy-aware error correction training algorithm using machine learning techniques from coding theory to generate optimal error-correction transformations. A redundancy calculator 2833 determines the optimal amount and distribution of redundant information required to achieve target error correction capabilities while minimizing overhead. An error detection optimizer 2834 maximizes the system's ability to identify when errors have occurred in transmitted or stored data. A recovery efficiency analyzer 2835 evaluates and optimizes the effectiveness of error correction mechanisms to ensure maximum error resilience with minimal additional data requirements. A correction capability validator 2836 tests and validates the error correction performance of generated codebooks under various failure scenarios to ensure reliable operation.

ML codebook generator cluster 2800 incorporates shared infrastructure components that coordinate the operation of the three specialized generators to ensure optimal overall system performance. A central training coordinator 2840 manages the training process across all generator subsystems, implementing the adaptive multi-objective codebook training (AMOCT) algorithm that balances competing objectives and ensures coherent system operation. A model synchronizer 2841 coordinates updates and parameter adjustments across the various specialized machine learning models to maintain consistency and prevent conflicting optimizations. A performance aggregator 2842 collects and analyzes performance metrics from all generators and downstream processing components to provide comprehensive feedback for system optimization. A resource manager 2843 allocates computational and memory resources across the three training processes, dynamically adjusting resource distribution based on current training loads and performance requirements.

A multi-objective training pipeline 2850 implements one or more advanced algorithms for coordinating the training of multiple machine learning models with potentially conflicting objectives. According to an aspect, multi-objective training pipeline 2850 comprises an AMOCT controller 2851 that implements the core multi-objective optimization algorithm that simultaneously optimizes compression efficiency, cryptographic strength, and error correction capability using modified Pareto optimization combined with reinforcement learning techniques. AMOCT controller 2851 manages multi-objective loss functions, implements weight adaptation algorithms that automatically adjust the relative importance of different objectives based on current performance and application requirements, and monitors convergence characteristics across all specialized models. A cross-stream loss calculator 2852 evaluates the interactions and dependencies between the various codebook generators, calculating coherence loss that ensures improvements in one processing arca do not compromise performance in others, performing interdependency analysis to identify optimization opportunities, and implementing global optimization strategies that consider the entire system rather than individual components. A gradient coordinator 2853 may be present and configured to manage the complex process of updating multiple machine learning models simultaneously, implementing multi-model update strategies that prevent conflicting parameter adjustments, adapting learning rates based on convergence characteristics of different models, and coordinating momentum across all training processes. A validation engine 2854 provides comprehensive testing and validation of generated codebooks before deployment, implementing model performance testing that evaluates the various codebook types under realistic operating conditions, performing cross-validation to ensure robustness across different data types and operating scenarios, and assessing deployment readiness to determine when generated codebooks meet quality and performance requirements.

The system incorporates comprehensive data flow management that coordinates training data distribution and model interaction across the cluster. Training data from content analysis engine 2710 flows to central training coordinator 2840, which distributes appropriate data subsets to each of the specialized generators 2810-2830 based on their specific training requirements. Performance metrics collected by performance aggregator 2842 are processed by AMOCT controller 2851 to generate model updates that are distributed by model synchronizer 2841 to ensure coordinated improvement across all three subsystems. Generated codebooks from codebook validators 2816, 2826, 2836 are processed by validation engine 2854 before being deployed to the appropriate stream processors 2750-2770 for operational use.

An adaptive learning feedback loop 2860 enables continuous improvement and optimization of ML codebook generator cluster 2800 based on runtime performance data. Adaptive learning feedback loop 2860 comprises mechanisms that collect runtime performance data from performance monitor 2786 through performance aggregator 2842, which analyzes the effectiveness of deployed codebooks under actual operating conditions. This performance data is processed by model refinement systems 2787 that identify opportunities for improvement and generate updated training parameters. The refined parameters are used by codebook evolver 2789 to generate updated codebooks with improved performance characteristics, creating a continuous learning system that adapts to changing data characteristics and operational requirements.

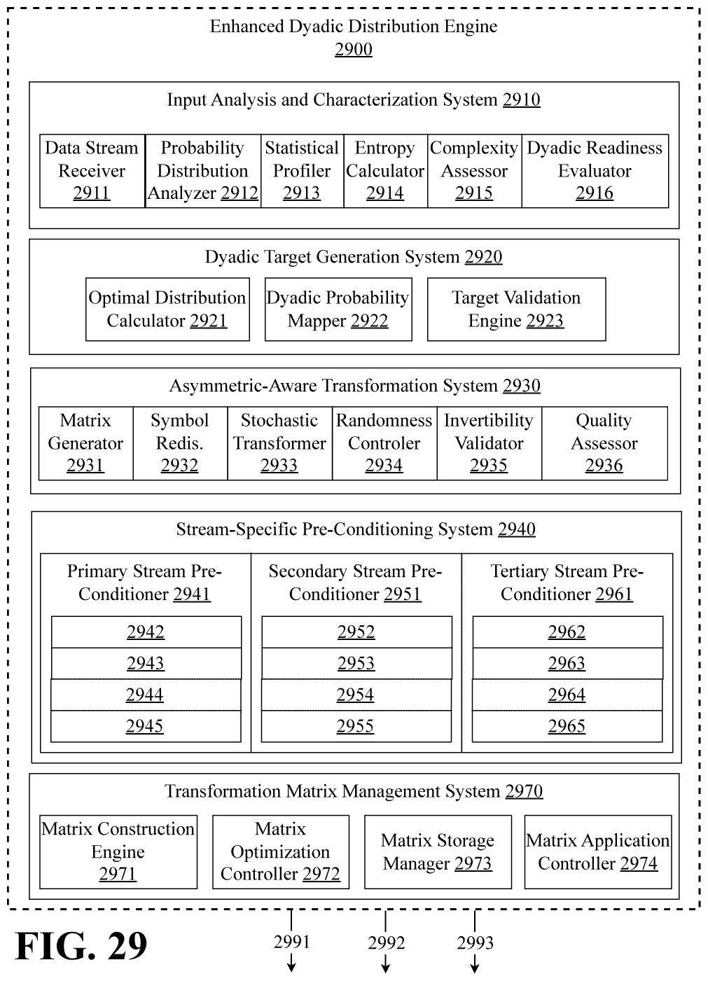

FIG. 29 is a block diagram illustrating an exemplary aspect of the cross-stream asymmetric system, an enhanced dyadic distribution engine that implements one or more dyadic distribution algorithms specifically optimized for multi-stream processing and asymmetric codebook compatibility.

According to an embodiment, enhanced dyadic distribution engine 2900 comprises a input analysis and characterization system 2910 that performs detailed evaluation of incoming data characteristics to determine optimal processing strategies. Input analysis and characterization system 2910 may comprise a data stream receiver 2911 that accepts input data from content analysis engine 2710 and performs initial data formatting and validation to ensure compatibility with subsequent processing stages. A probability distribution analyzer 2912 examines the statistical characteristics of the incoming data stream, calculating symbol frequencies, probability distributions, and statistical moments that provide information for dyadic optimization. A statistical profiler 2913 creates comprehensive profiles of data characteristics including, but not limited to, pattern recognition, correlation analysis, and predictability assessment that guide transformation strategy selection. An entropy calculator 2914 measures the information content and randomness characteristics of the input data to establish baseline entropy metrics for optimization targeting. A complexity assessor 2915 evaluates the computational complexity requirements for achieving optimal dyadic distributions based on current data characteristics and processing objectives. A dyadic readiness evaluator 2916 determines how closely the current data distribution aligns with ideal dyadic probability characteristics and estimates the transformation effort required to achieve target distributions.

According to an embodiment, enhanced dyadic distribution engine 2900 comprises a dyadic target generation system 2920 that creates optimal target probability distributions specifically designed for multi-stream processing requirements. Dyadic target generation system 2920 may comprise an optimal distribution calculator 2921 that determines the ideal dyadic probability distributions for the specific input data characteristics, considering both compression efficiency and compatibility with downstream asymmetric processing. A dyadic probability mapper 2922 can create mappings between current symbol probabilities and target dyadic probabilities, implementing one or more algorithms that balance transformation complexity against optimization effectiveness. A target validation engine 2923 verifies that generated target distributions will achieve desired performance characteristics and validates mathematical correctness and feasibility of the proposed transformations.

The system implements an asymmetric-aware transformation system 2930 that performs the core dyadic distribution transformation while maintaining compatibility with subsequent asymmetric codebook processing. Asymmetric-aware transformation system 2930 comprises a transformation matrix generator 2931 that creates the mathematical transformation matrices required to convert input probability distributions to target dyadic distributions, incorporating constraints and optimizations that ensure compatibility with stream-specific asymmetric processing. A symbol redistributor 2932 implements the actual redistribution of symbol frequencies to achieve target dyadic probabilities, utilizing one or more algorithms that maintain information content while optimizing statistical characteristics. A stochastic transformer 2933 applies controlled randomness during the transformation process to achieve desired statistical properties while maintaining deterministic reconstruction capability for authorized users. A randomness controller 2934 manages the injection and control of randomness throughout the transformation process to ensure optimal cryptographic properties while maintaining system functionality. An invertibility validator 2935 ensures that all transformations maintain the mathematical properties necessary for complete data reconstruction, preventing information loss during the transformation process. A quality assessor 2936 evaluates the effectiveness of applied transformations by measuring, for example, achievement of target dyadic distributions and assessing overall system performance.

According to an embodiment, enhanced dyadic distribution engine 2900 incorporates a stream-specific pre-conditioning system 2940 that can be configured for preparing transformed data specifically for optimal performance in each of the one or more asymmetric processing streams. Stream-specific pre-conditioning system 2940 comprises various specialized pre-conditioning subsystems, each optimized for different processing objectives. A primary stream pre-conditioner 2941 optimizes dyadic-transformed data specifically for compression-focused asymmetric processing and comprises a compression optimizer 2942 that adjusts transformation parameters to maximize compression potential of the dyadic-transformed data. Primary stream pre-conditioner 2941 also includes a Huffman predictor 2943 that estimates and optimizes the effectiveness of subsequent Huffman coding on the pre-conditioned data, an entropy maximizer 2944 that fine-tunes entropy characteristics to achieve optimal compression performance, and a compression-ready formatter 2945 that formats the pre-conditioned data in the optimal structure for compression-focused asymmetric codebook processing.

According to an embodiment, a secondary stream pre-conditioner 2951 optimizes dyadic-

transformed data specifically for security-focused asymmetric processing and comprises a security enhancer 2952 that adjusts transformation parameters to maximize cryptographic strength and resistance to analysis while maintaining functional relationships necessary for authorized reconstruction. Secondary stream pre-conditioner 2951 includes a randomness injector 2953 that introduces additional controlled randomness to enhance cryptographic properties, a pattern obfuscator 2954 that eliminates recognizable patterns that could facilitate unauthorized analysis, and a security-ready formatter 2955 that structures the pre-conditioned data for optimal security-focused asymmetric codebook processing.

According to an embodiment, a tertiary stream pre-conditioner 2961 optimizes dyadic-transformed data specifically for error-correction-focused asymmetric processing and comprises an error pattern analyzer 2962 that examines the data for characteristics that influence error detection and correction capability, identifying optimal strategies for embedding redundant information. Tertiary stream pre-conditioner 2961 includes a redundancy planner 2963 that determines optimal distribution and placement of redundant information to maximize error correction capability while minimizing overhead, a recovery optimizer 2964 that optimizes data structures to enable efficient error detection and correction under various failure scenarios, and an error-correction-ready formatter 2965 that formats the pre-conditioned data for optimal error-correction-focused asymmetric codebook processing.

According to an aspect of an embodiment, enhanced dyadic distribution engine 2900 implements a transformation matrix management system 2970 that handles the complex mathematical operations required for dyadic distribution transformation while maintaining system performance and reliability. Transformation matrix management system 2970 may comprise a matrix construction engine 2971 that builds the transformation matrices required for dyadic conversion, implementing row-stochastic validation to ensure proper probability preservation, invertibility assurance to guarantee complete data reconstruction capability, and numerical stability checks to prevent computational errors. A matrix optimization controller 2972 optimizes matrix characteristics for performance and effectiveness, implementing convergence optimization to ensure rapid achievement of target distributions, performance balancing to maintain optimal trade-offs between competing objectives, and efficiency maximization to minimize computational overhead. A matrix storage manager 2973 handles the storage and management of transformation matrices, implementing compressed matrix storage to minimize memory requirements, version control to track matrix evolution and enable rollback capabilities, and recovery metadata management to ensure reliable system operation. A matrix application controller 2974 manages the real-time application of transformation matrices to data streams, implementing real-time application algorithms that maintain system throughput, performance monitoring to track transformation effectiveness, and error handling to ensure reliable operation under adverse conditions.

The system may further comprise an adaptive optimization and feedback system that enables continuous improvement and optimization of dyadic distribution processing based on performance feedback and changing requirements. In some implementations of an embodiment, the adaptive optimization and feedback system comprises a performance monitor that tracks system performance across multiple metrics including compression efficiency tracking to measure the effectiveness of compression-optimized pre-conditioning, security metric analysis to evaluate the cryptographic strength achieved by security-optimized pre-conditioning, and error correction effectiveness assessment to measure the reliability improvements achieved by error-correction-optimized pre-conditioning. An adaptive parameter controller implements real-time adjustment of processing parameters based on performance feedback and changing conditions, including real-time parameter adjustment that responds to performance variations, content-based optimization that adapts processing strategies to different data types, and performance balancing that maintains optimal trade-offs between competing objectives. A feedback integrator coordinates feedback and optimization across the entire system, implementing cross-stream coordination to ensure that optimizations in one stream do not compromise performance in others, system-wide optimization that considers global performance rather than individual component optimization, and learning integration that incorporates insights from machine learning systems to improve processing effectiveness.

Enhanced dyadic distribution engine 2900 generates multiple specialized output streams that are optimally prepared for their respective asymmetric processing stages. Three exemplary output streams are shown. A pre-conditioned primary stream 2991 contains dyadic-transformed data that has been specifically optimized for compression-focused asymmetric processing, with probability distributions and structural characteristics that enable maximum compression efficiency in subsequent processing stages. A pre-conditioned secondary stream 2992 contains dyadic-transformed data that has been specifically optimized for security-focused asymmetric processing, with enhanced randomness characteristics and obfuscated patterns that enable maximum cryptographic strength in subsequent processing stages. A pre-conditioned tertiary stream 2993 contains dyadic-transformed data that has been specifically optimized for error-correction-focused asymmetric processing, with redundancy patterns and structural characteristics that enable maximum error detection and correction capability in subsequent processing stages. These three exemplary pre-conditioned streams can be output to stream separator 2740 for distribution to their respective asymmetric processing pipelines.

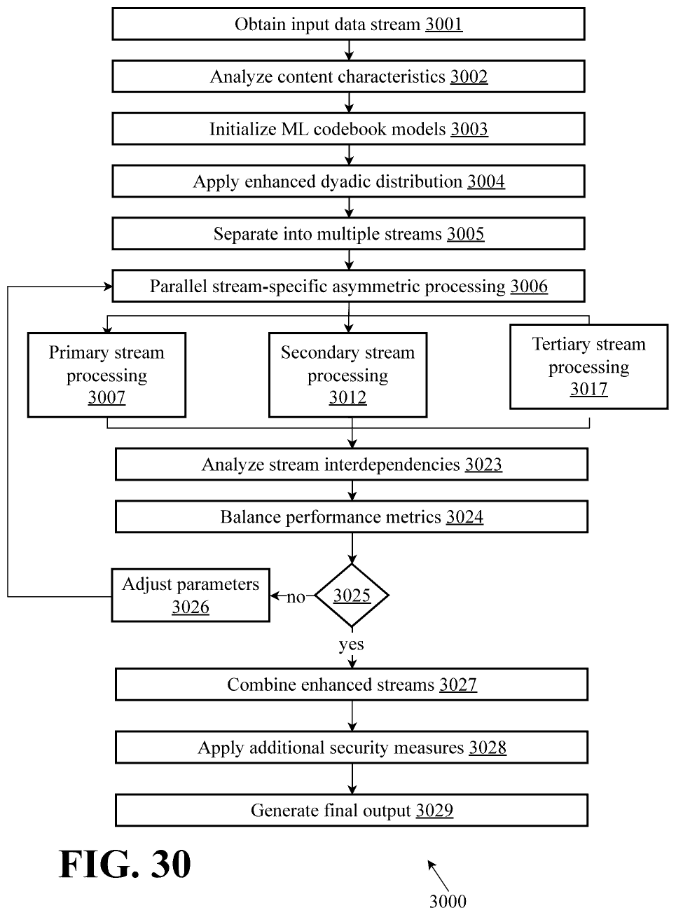

FIG. 30 is a flow diagram illustrating an exemplary method 3000 for cross-stream asymmetric enhancement processing that combines dyadic distribution algorithms with stream-specific asymmetric codebook transformations to achieve simultaneous compression, encryption, and error correction optimization, according to an embodiment. Method 3000 represents an approach to data processing that leverages machine learning, adaptive optimization, and multi-objective coordination to achieve performance characteristics that exceed conventional single-objective processing approaches.

According to the embodiment, the process begins at step 3001 with receiving, retrieving, or otherwise obtaining an input data stream from a source system, where the method performs initial validation, formatting, and buffering operations to prepare the data for subsequent processing stages. The input data stream may comprise various data types including, but in no way limited to, video content, medical imaging data, financial information, or other digital content requiring secure and efficient transmission or storage.

At step 3002, the method analyzes content characteristics by performing comprehensive evaluation of data properties including, but not limited to, complexity assessment to determine computational requirements, sensitivity analysis to establish security requirements, compression potential evaluation to identify optimization opportunities, and error correction needs assessment to determine reliability requirements. This analysis provides foundational information that can guide subsequent processing decisions and optimization strategies throughout the method execution.

Step 3003 initializes ML codebook models by configuring multiple specialized machine learning models based on the content analysis results from step 3002. The method initializes a compression-optimized model trained to generate asymmetric codebooks that maximize data reduction while preserving reconstruction fidelity, a security-optimized model designed to create codebooks that maximize cryptographic strength and resistance to attack vectors, and an error-correction-optimized model configured to generate codebooks that enhance error detection and correction capabilities while minimizing redundancy overhead. Each model is initialized with parameters specifically adapted to the analyzed content characteristics to ensure optimal performance for the specific data being processed.

At step 3004, the method applies enhanced dyadic distribution processing by transforming the input data using one or more algorithms that create probability distributions optimized for both compression effectiveness and compatibility with subsequent asymmetric processing. The enhanced dyadic distribution processing incorporates stream-specific pre-conditioning that prepares the transformed data for optimal performance in each of the three asymmetric processing pipelines, ensuring that the dyadic transformation enhances rather than compromises the effectiveness of subsequent processing stages.

Step 3005 separates the dyadic-processed data into multiple distinct streams, each pre-conditioned for specific asymmetric processing objectives. The method creates a primary stream containing data optimized for compression-focused asymmetric processing with probability distributions and structural characteristics that enable maximum compression efficiency, a secondary stream containing data optimized for security-focused asymmetric processing with enhanced randomness characteristics and obfuscated patterns, and a tertiary stream containing data optimized for error-correction-focused asymmetric processing with redundancy patterns and structural characteristics that enable maximum error detection and correction capability.

The method implements parallel stream-specific asymmetric processing 3006 that simultaneously processes the three separated streams using specialized algorithms optimized for each stream's specific objectives. According to an embodiment, primary stream processing 3007 may comprise generating a compression codebook using machine learning algorithms trained specifically for compression optimization, applying asymmetric transformation that converts the primary stream data into representations optimized for compression while maintaining reconstruction capability, optimizing for Huffman coding by fine-tuning the transformed data characteristics to achieve maximum efficiency with entropy coding algorithms, and validating compression efficiency to ensure that the processing achieves target compression ratios while maintaining acceptable quality levels.

According to an embodiment, secondary stream processing 3012 may comprise generating a security codebook using adversarial training algorithms designed to maximize cryptographic strength, applying cryptographic transformation that converts the secondary stream data into representations with enhanced security properties while preserving necessary functional relationships, enhancing security properties through additional randomness injection and pattern obfuscation techniques, and validating cryptographic strength to ensure that the processing achieves target security levels and resistance to various attack methodologies.

According to an embodiment, tertiary stream processing 3017 may comprise generating an error-correction codebook using machine learning algorithms trained on various error models to maximize detection and correction capabilities, applying redundancy transformation that converts the tertiary stream data into representations with embedded error correction information, optimizing error detection by enhancing the system's ability to identify when errors have occurred in transmitted or stored data, and validating recovery capability to ensure that the processing achieves target error correction performance under various failure scenarios.

Cross-stream optimization and coordination implements one or more algorithms that coordinate the three parallel processing streams to ensure optimal overall system performance. Step 3023 analyzes stream interdependencies by evaluating the interactions between the three processed streams, identifying optimization opportunities that consider the entire system rather than individual components, and ensuring that improvements in one processing arca do not compromise performance in others. Step 3024 balances performance metrics by dynamically adjusting processing parameters to achieve optimal trade-offs between compression efficiency, security strength, and error correction capability based on application requirements and current performance characteristics.

The method may further comprise a quality assessment decision point 3025 that determines whether the processed streams meet acceptable quality standards and performance requirements. If quality is not acceptable, the method proceeds to step 3026 to adjust parameters by modifying processing algorithms, updating transformation matrices, or revising optimization targets before returning to earlier processing stages for reprocessing. If quality is acceptable, the method continues to step 3027.

Step 3027 combines enhanced streams according to application requirements and selected operating mode, implementing algorithms that can operate in ultra-high compression mode using only the primary stream for maximum bandwidth efficiency, broadcast quality mode using primary and secondary streams for professional quality standards, or archival mode using all three streams for lossless reconstruction capability. The combination process considers the specific requirements of the target application and optimizes the output format accordingly.

At step 3028, the method applies additional security measures including, but not limited to, frame-shuffling algorithms that scramble data order using dyadic-based permutation techniques, temporal encryption layering that applies different protection levels based on data importance and characteristics, and stream interleaving that combines the selected streams using content-based prioritization algorithms. These additional security measures provide multiple layers of protection that enhance the overall security effectiveness of the system.

Step 3029 generates final output by producing compressed and encrypted output streams according to the selected operating mode and application requirements. The output generation process formats the data for optimal compatibility with target transmission or storage systems, includes necessary metadata and reconstruction information, and implements quality validation to ensure that the final output meets all specified requirements.

The method may further include a processing continuation decision point that determines whether to continue processing additional data or terminate the current processing session. If processing should continue, the method returns to step 3001 to process additional input data, leveraging the optimized parameters and models developed during previous processing cycles. If processing should terminate, the method ends.

In at least one embodiment, method 3000 incorporates an adaptive learning feedback loop that enables continuous improvement and optimization of processing effectiveness based on operational experience and performance feedback. The feedback loop comprises monitoring performance by tracking compression ratios, security effectiveness, error correction capability, and overall system efficiency across multiple processing sessions. The method updates ML models by incorporating performance feedback into the training algorithms, enabling the machine learning systems to adapt to encountered data patterns and improve processing effectiveness over time. Codebook evolution implements algorithms that refine and improve the asymmetric codebooks based on operational experience, creating increasingly effective transformations as the system processes more data. Parameter optimization continuously adjusts processing parameters throughout the system based on performance feedback and changing requirements, ensuring that the method maintains optimal performance even as data characteristics and operational conditions change.

The adaptive learning feedback loop provides continuous improvement capabilities that enable method 3000 to achieve increasingly effective performance over time, adapting to new data types, changing requirements, and evolving operational conditions. This adaptive capability ensures that the method maintains optimal effectiveness even in dynamic environments where data characteristics and processing requirements may change significantly over time, providing long-term value and reliability that exceeds static processing approaches.

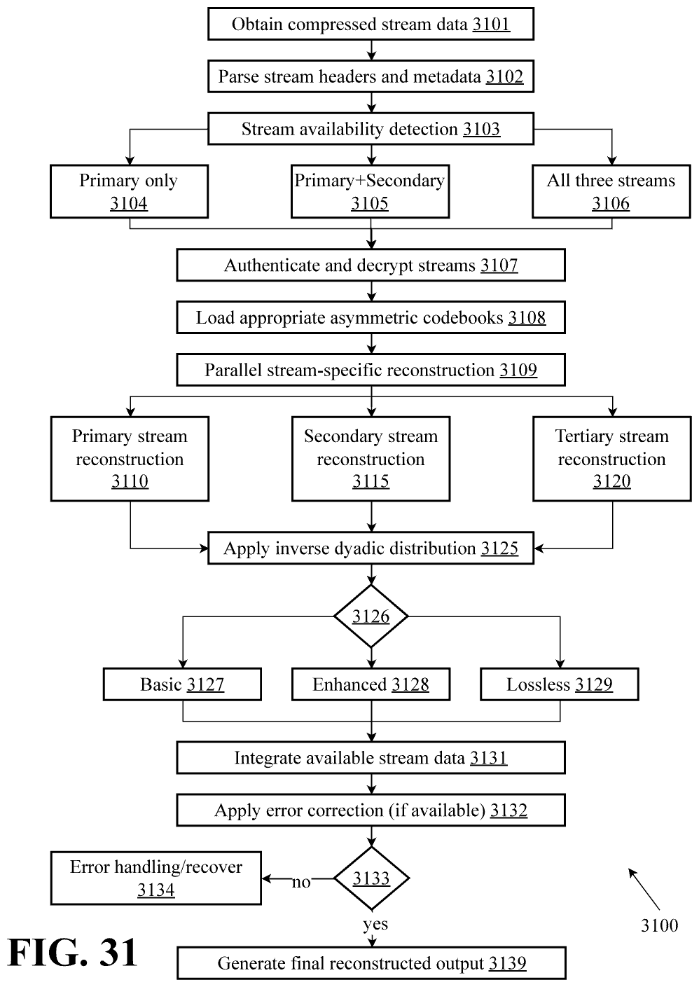

FIG. 31 is a flow diagram illustrating an exemplary method 3100 for multi-stream reconstruction that processes compressed and encrypted data streams generated by the cross-stream asymmetric enhancement system to reconstruct original data with varying levels of quality based on available stream combinations, according to an embodiment. Method 3100 represents an approach to data reconstruction that enables graduated access control, adaptive quality management, and robust error recovery while maintaining security and efficiency characteristics of the original processing system.

According to the embodiment, the process begins at step 3101 with obtaining compressed stream data from transmission or storage sources, where the method performs initial validation to ensure data integrity, implements buffering operations to manage data flow, and establishes communication protocols with source systems. The received data may comprise one, two, or three distinct streams depending on the processing mode used during encoding and the security or quality requirements of the reconstruction application.

At step 3102, the method parses stream headers and metadata to extract critical information necessary for reconstruction operations. This parsing operation may identify stream configuration information that indicates which processing mode was used during encoding, extracts processing mode indicators that specify whether data was encoded in ultra-high compression, broadcast quality, or archival mode, retrieves codebook references that identify the specific asymmetric codebooks required for reconstruction, and recovers reconstruction parameters including transformation matrices, quality targets, and compatibility information necessary for proper data reconstruction.

Stream availability detection 3103 analyzes the received data to determine which reconstruction capabilities are available based on the stream combinations present. The method identifies three possible configurations: primary only 3104 indicating ultra-high compression mode where only basic reconstruction capability is available using the primary stream alone, primary plus secondary 3105 indicating broadcast quality mode where enhanced reconstruction quality is achievable by combining primary and secondary streams, and all three streams 3106 indicating archival mode where lossless reconstruction capability is available using comprehensive data from all three streams.

Step 3107 authenticates and decrypts streams by implementing security validation procedures to verify stream integrity and authenticity, applying appropriate decryption algorithms based on the security methods used during encoding, and validating digital signatures or authentication codes to ensure that streams have not been tampered with during transmission or storage. This security processing ensures that only authorized users can access the encoded data and that any unauthorized modifications are detected and rejected.

At step 3108, the method loads appropriate asymmetric codebooks corresponding to the available streams based on header information and processing mode indicators. The method retrieves compression-optimized codebooks for primary stream reconstruction, security-optimized codebooks for secondary stream reconstruction when available, and error-correction-optimized codebooks for tertiary stream reconstruction when available. Each codebook is validated to ensure compatibility with the encoded data and initialized with appropriate parameters for reconstruction operations.

The method implements parallel stream-specific reconstruction 3109 that simultaneously processes available streams using specialized algorithms optimized for each stream's characteristics. According to an embodiment, primary stream reconstruction 3110 may comprise applying inverse asymmetric transform to reverse the compression-optimized asymmetric encoding and restore dyadic-transformed data, reversing compression optimization to undo compression-specific pre-conditioning and restore standard probability distributions, applying Huffman decoding to convert compressed codewords back to symbol representations, and generating basic content data that provides fundamental reconstruction capability suitable for basic viewing or processing applications.

According to an embodiment, secondary stream reconstruction 3115 may comprise applying inverse security transform to reverse the security-optimized asymmetric encoding while maintaining cryptographic validation, recovering transformation matrices that contain the mathematical information necessary for enhanced reconstruction quality, extracting enhancement data including motion vectors, frame relationships, and processing parameters that enable improved reconstruction, and generating quality enhancement information that enables superior reconstruction quality when combined with primary stream data.

According to an embodiment, tertiary stream reconstruction 3120 comprises applying inverse error-correction transform to reverse the error-correction-optimized asymmetric encoding and access embedded recovery information, extracting error correction data including redundancy information and error detection codes that enable comprehensive error recovery, recovering complete metadata including timing information, structural data, and processing parameters necessary for perfect reconstruction, and generating lossless recovery information that enables complete restoration of original data characteristics when combined with data from other streams.

Step 3125 applies inverse dyadic distribution processing using recovered transformation matrices to reverse the dyadic distribution transformations applied during encoding and restore original data probability distributions. This step utilizes the transformation matrices recovered from secondary or tertiary streams when available, or implements best-effort reconstruction using primary stream data alone when higher-level streams are not available.

Reconstruction quality selection 3126 determines the achievable reconstruction quality based on available stream data and selects appropriate processing algorithms. Basic quality 3127 can utilize only primary stream data to provide fundamental reconstruction capability with acceptable quality for bandwidth-constrained applications. Enhanced quality 3128 can combine primary and secondary stream data to achieve professional-grade reconstruction suitable for broadcast and commercial applications. Lossless quality 3129 may utilize all three streams to achieve perfect reconstruction that matches the original data characteristics exactly.

Multi-stream data integration coordinates the combination of data from available streams to achieve optimal reconstruction results. Step 3131 integrates available stream data by combining information from multiple streams according to their hierarchy and interdependencies, implementing algorithms that optimize the contribution of each stream based on its characteristics and quality, and ensuring that the integration process maintains temporal relationships and structural integrity necessary for proper data utilization. Step 3132 applies error correction when tertiary stream data is available, using embedded error correction information to detect and correct transmission or processing errors, implementing recovery algorithms that can restore corrupted data using redundancy information, and validating the effectiveness of error correction to ensure reliable reconstruction results.

The method includes a quality validation decision point 3133 that determines whether reconstruction quality meets acceptable standards and application requirements. If quality is not satisfactory, the method proceeds to error handling and recovery 3134 that implements multiple recovery strategies. Alternative reconstruction methods attempt different reconstruction algorithms or parameter settings to achieve acceptable quality. Stream retransmission request contacts source systems to request retransmission of corrupted or missing stream data. Quality assessment report generation documents reconstruction quality issues and provides feedback for system optimization. Graceful degradation implements fallback strategies that provide the best possible reconstruction quality given available data and processing constraints.

Step 3139 generates final reconstructed output by formatting reconstructed data according to target application specifications, implementing appropriate data structures and metadata for application compatibility, and ensuring that output quality indicators accurately reflect the reconstruction capabilities and limitations. The output generation process considers the specific requirements of target applications and optimizes formatting for maximum compatibility and usability.

According to a further aspect, the method can verify reconstruction integrity by performing comprehensive validation of reconstructed data quality, implementing integrity checks that validate mathematical correctness and structural consistency, measuring reconstruction quality metrics including signal-to-noise ratios, compression effectiveness, and error rates, and ensuring compatibility with target application requirements including format specifications, timing constraints, and quality standards.

In some aspects, the method comprises a processing continuation decision point that determines whether additional data requires processing. If more data is available, the method returns to step 3101 to process additional streams, leveraging optimized parameters and validated codebooks from previous reconstruction operations. If no additional data requires processing, the method proceeds to deliver reconstructed data to target applications or users with comprehensive documentation of reconstruction characteristics. The delivery process may comprise providing quality indicators that inform users about reconstruction fidelity and limitations, supplying usage metadata that describes optimal application scenarios and constraints, and implementing appropriate formatting and protocols for seamless integration with target systems. The method concludes after successful delivery of reconstructed data.

Method 3100 provides reconstruction capabilities that enable flexible quality management, robust error recovery, and graduated access control while maintaining the security and efficiency benefits of the cross-stream asymmetric enhancement system. The method's adaptive approach ensures optimal reconstruction quality given available stream data while providing graceful degradation capabilities that maintain functionality even under adverse conditions or limited data availability.

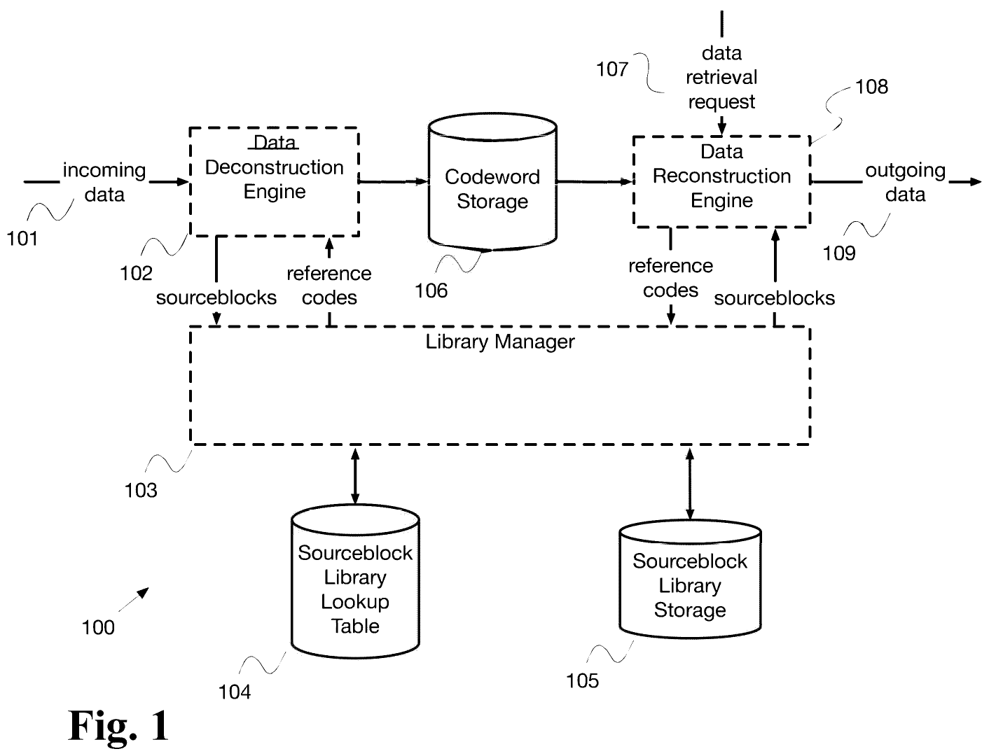

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

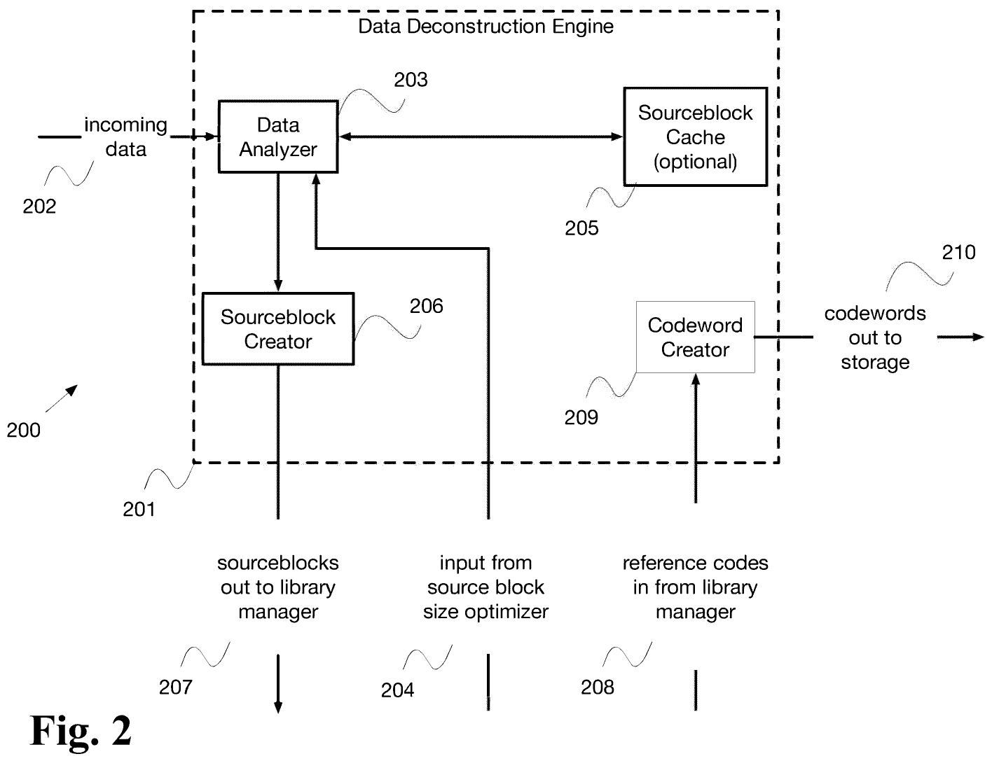

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

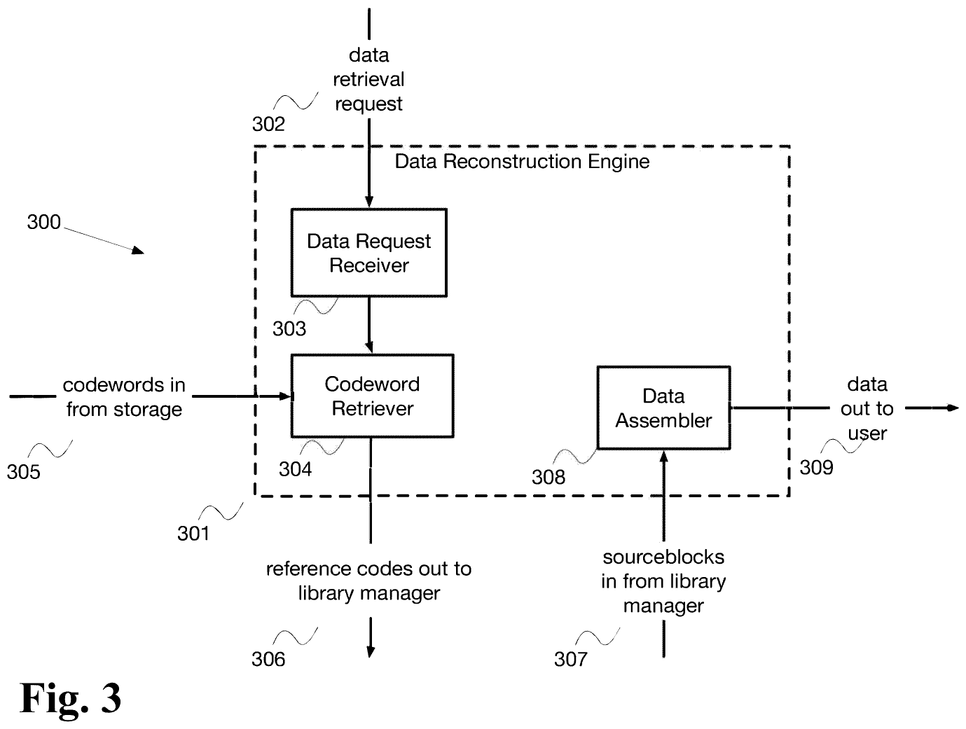

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

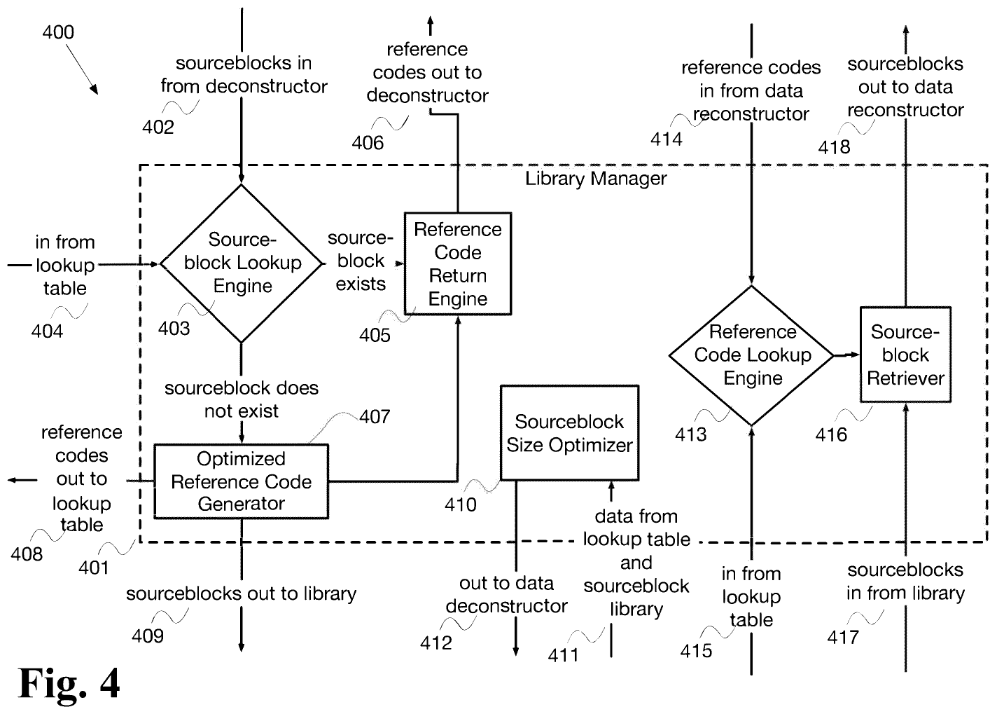

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

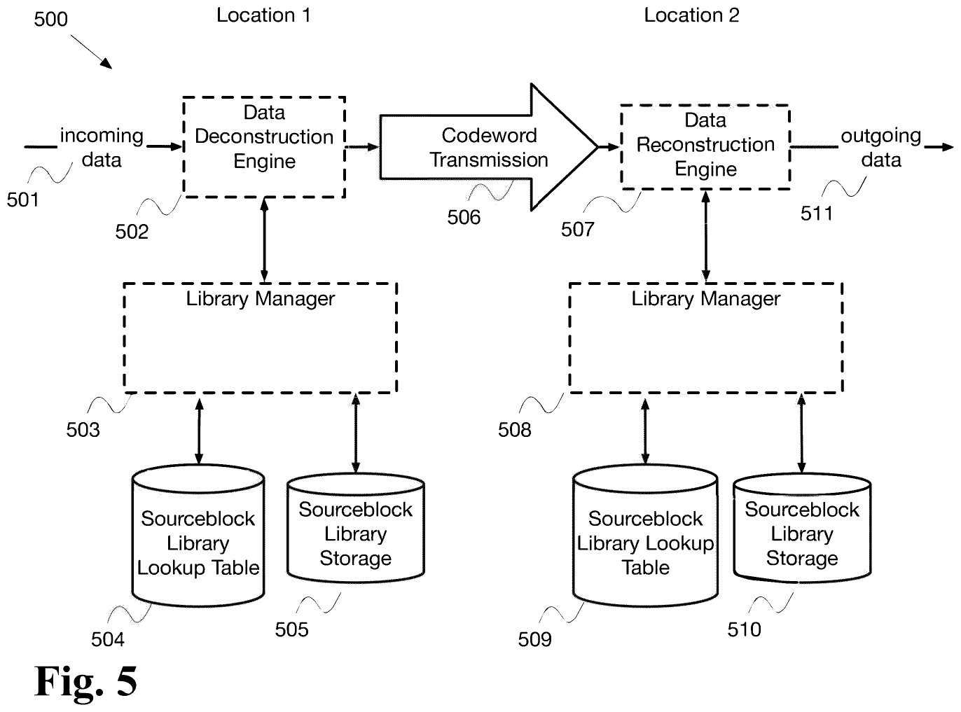

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2, and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

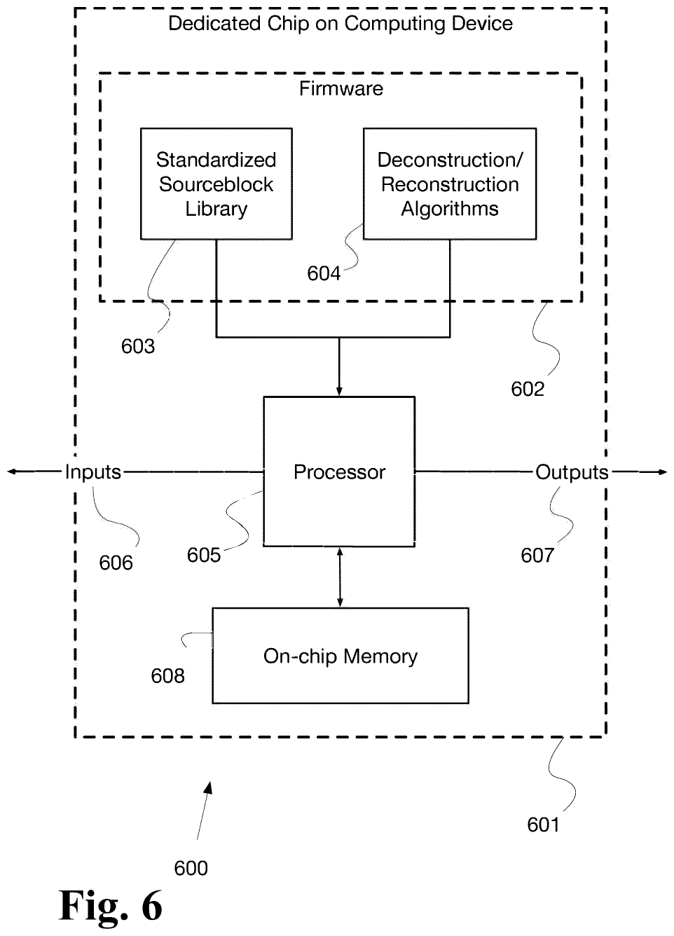

FIG. 6 is a diagram showing an embodiment 600 in which a standardized version of a sourceblock library 603 and associated algorithms 604 would be encoded as firmware 602 on a dedicated processing chip 601 included as part of the hardware of a plurality of devices 600. Contained on dedicated chip 601 would be a firmware arca 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device's 600 primary processors. Any device equipped with this embodiment would be able to store and transmit data in a highly optimized, bandwidth-efficient format with any other device equipped with this embodiment.

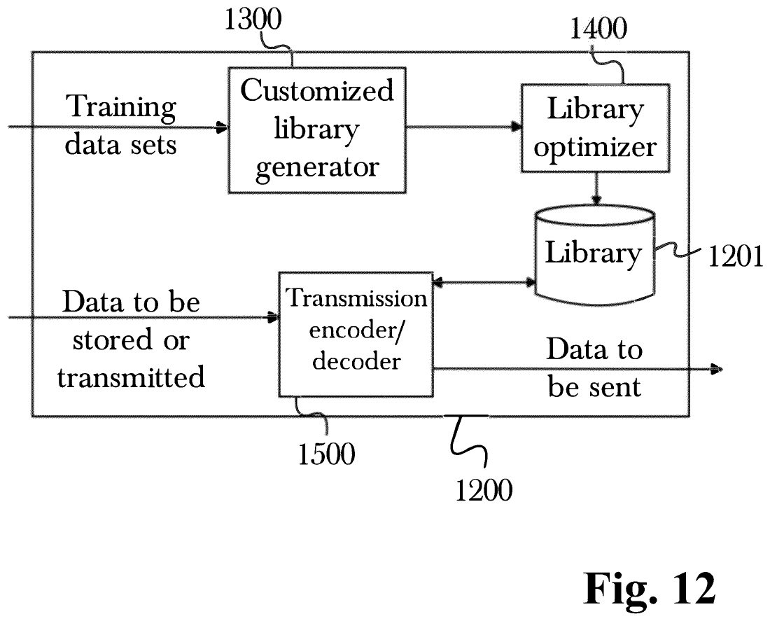

FIG. 12 is a diagram showing an exemplary system architecture 1200, according to a preferred embodiment of the invention. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is R_{C} bit/s and the decoding rate is R_{D} bit/s, and the transmission speed is S bit/s, the compress-send-decompress time will be

$${T}_{old} = \frac{N}{{R}_{C}} + \frac{N}{CS} + \frac{N}{{CR}_{D}}$$

while the transmit-while-coding time for system 1200 will be (assuming that encoding and decoding happen at least as quickly as network latency):

$${T}_{new} = \frac{{N}_{p}}{CS} so$$

that the total data transit time improvement factor is

$$\frac{{T}_{old}}{{T}_{new}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1.$$

This is a reasonable scenario given that typical values in real-world practice are C=0.32, R_{C}=1.1·10¹², R_{D}=4.2·10¹², S=10¹¹, giving

$$\frac{CS}{{R}_{C}} + \frac{S}{{R}_{D}} = 0.053 ... ,$$

such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{tp}{CS}$$

since encoding and decoding occur concurrently with data transmission. On the other hand, the latency associated with classical compression is

$${delay}_{priorart} = \frac{N}{{R}_{C}} + \frac{N}{CS} + \frac{N}{{CR}_{D}}$$

where N is the packet/file size. Even with the generous values chosen above as well as N=512K, t=10, and p=1.05, this results in delayᵢₙᵥₑₙₜᵢₒₙ˜3.3·10⁻¹⁰ while delayₚᵣᵢₒᵣₐᵣₜ˜1.3·10⁻⁷, a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

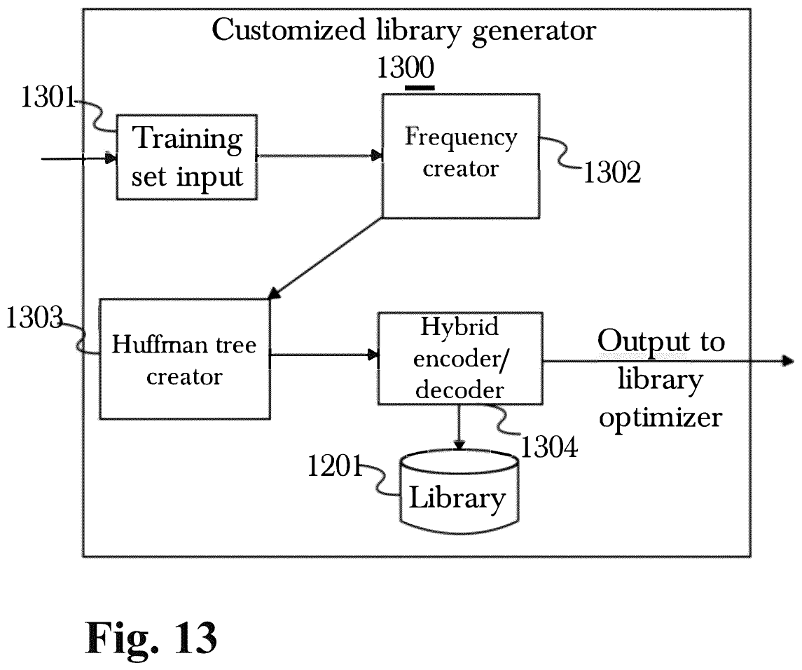

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

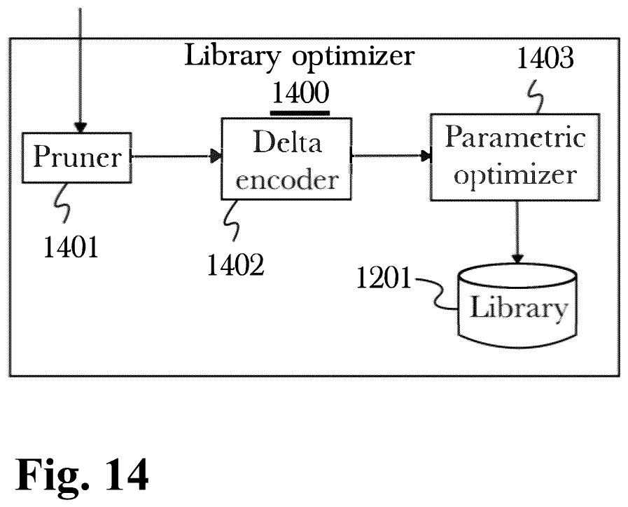

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

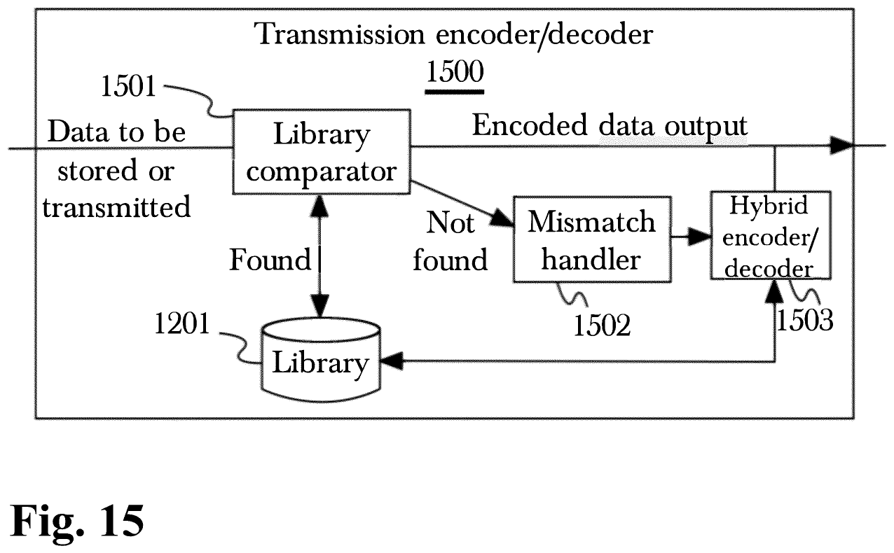

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords, and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

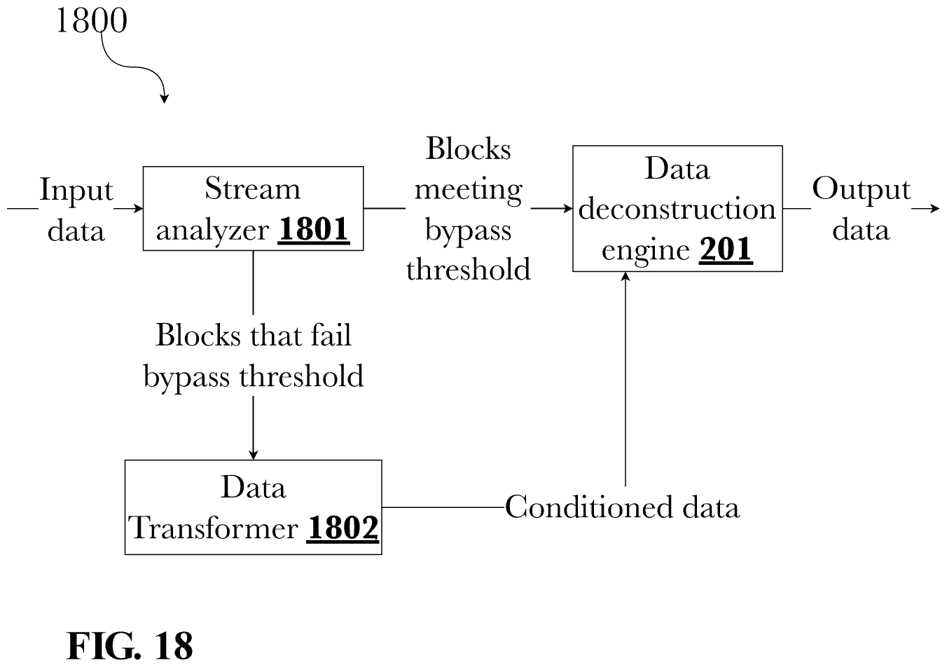

FIG. 18 is a block diagram illustrating an exemplary system architecture 1800 for combining data compression with encryption using split-stream processing. According to the embodiment, an incoming data stream can be compressed and encrypted simultaneously through the use of split-stream processing, wherein the data stream is broken into blocks that are compared against the stream as a whole to determine their frequency (i.e., their probability distribution within the data stream). Huffman coding works provably ideally when the elements being encoded have dyadic probabilities, that is probabilities that are all of the form 1/(2^{x}); in actual practice, not all data blocks will have a dyadic probability, and thus the efficiency of Huffman coding decreases. To improve efficiency while also providing encryption of the data stream, those blocks that have non-dyadic probability may be identified and replaced with other blocks, effectively shuffling the data blocks until all blocks present in the output stream have dyadic probability by using some blocks more frequently and others less frequently to “adjust” their probability within the output stream. For purposes of reconstruction, a second error stream is produced that contains the modifications made, so that the recipient need only compare the error stream against the received data stream to reverse the process and restore the data.

A stream analyzer 1801 receives an input data stream and analyzes it to determine the frequency of each unique data block within the stream. A bypass threshold may be used to determine whether the data stream deviates sufficiently from an idealized value (for example, in a hypothetical data stream with all-dyadic data block probabilities), and if this threshold is met the data stream may be sent directly to a data deconstruction engine 201 for deconstruction into codewords as described below in greater detail (with reference to FIG. 2). If the bypass threshold is not met, the data stream is instead sent to a stream conditioner 1802 for conditioning.

Stream conditioner 1802 receives a data stream from stream analyzer 1801 when the bypass threshold is not met, and handles the encryption process of swapping data blocks to arrive at a more-ideal data stream with a higher occurrence of dyadic probabilities; this facilitates both encryption of the data and greater compression efficiency by improving the performance of the Huffman coding employed by data deconstruction engine 201. To achieve this, each data block in the data stream is checked against a conditioning threshold using the algorithm |(P₁−P₂)|>T_{C}, where P₁ is the actual probability of the data block, P₂ is the ideal probability of the block (generally, the nearest dyadic probability), and T_{C} is the conditioning threshold value. If the threshold value is exceeded (that is, the data block's real probability is “too far” from the nearest ideal probability), a conditioning rule is applied to the data block. After conditioning, a logical XOR operation may be applied to the conditioned data block against the original data block, and the result (that is, the difference between the original and conditioned data) is appended to an error stream. The conditioned data stream (containing both conditioned and unconditioned blocks that did not meet the threshold) and the error stream are then sent to the data deconstruction engine 201 to be compressed, as described below in FIG. 2.

To condition a data block, a variety of approaches may be used according to a particular setup or desired encryption goal. One such exemplary technique may be to selectively replace or “shuffle” data blocks based on their real probability as compared to an idealized probability: if the block occurs less-frequently than desired or anticipated, it may be added to a list of “swap blocks” and left in place in the data stream; if a data block occurs more frequently than desired, it is replaced with a random block from the swap block list. This increases the frequency of blocks that were originally “too low”, and decreases it for those that were originally “too high”, bringing the data stream closer in line with the idealized probability and thereby improving compression efficiency while simultaneously obfuscating the data. Another approach may be to simply replace too-frequent data blocks with any random data block from the original data stream, eliminating the need for a separate list of swap blocks, and leaving any too-low data blocks unmodified. This approach does not necessarily increase the probability of blocks that were originally too-low (apart from any that may be randomly selected to replace a block that was too-high), but it may improve system performance due to the elimination of the swap block list and associated operations.

It should be appreciated that both the bypass and conditioning thresholds used may vary, for example, one or both may be a manually-configured value set by a system operator, a stored value retrieved from a database as part of an initial configuration, or a value that may be adjusted on-the-fly as the system adjusts to operating conditions and live data.

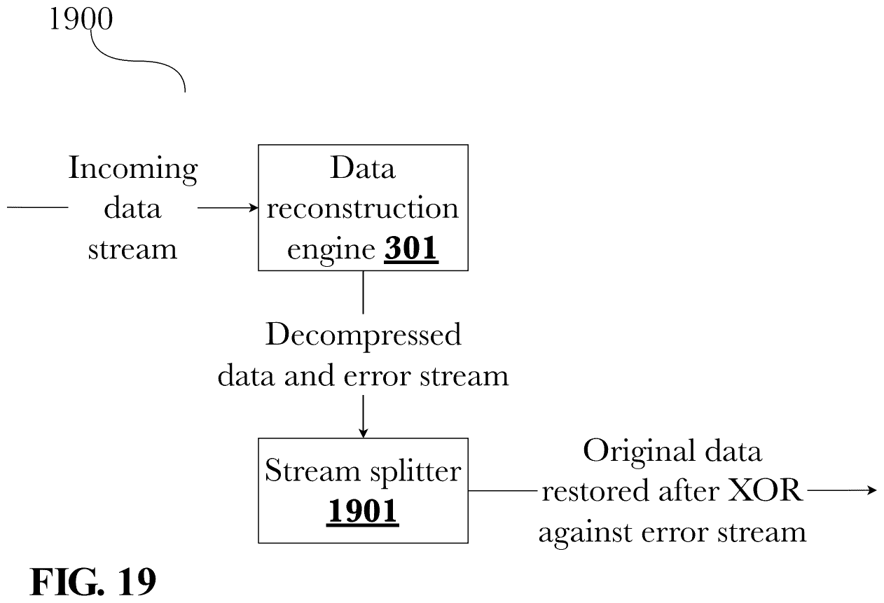

FIG. 19 is a block diagram illustrating an exemplary system architecture 1900 for decompressing and decrypting incoming data that was processed using split-stream processing. To decompress and decrypt received data, a data reconstruction engine 301 may first be used to reverse the compression on a data stream as described below in FIG. 3, passing the decompressed (but still encrypted) data to a stream splitter 1901. The corresponding error stream may be separated from the data stream (for example, the two streams may have been combined during compression but during decompression they are separated) or it may be received independently as a second data stream. Stream splitter 1901 applies XOR logical operations to each data block according to the error stream, reversing the original block conditioning process and restoring the original data on a block-by-block basis.

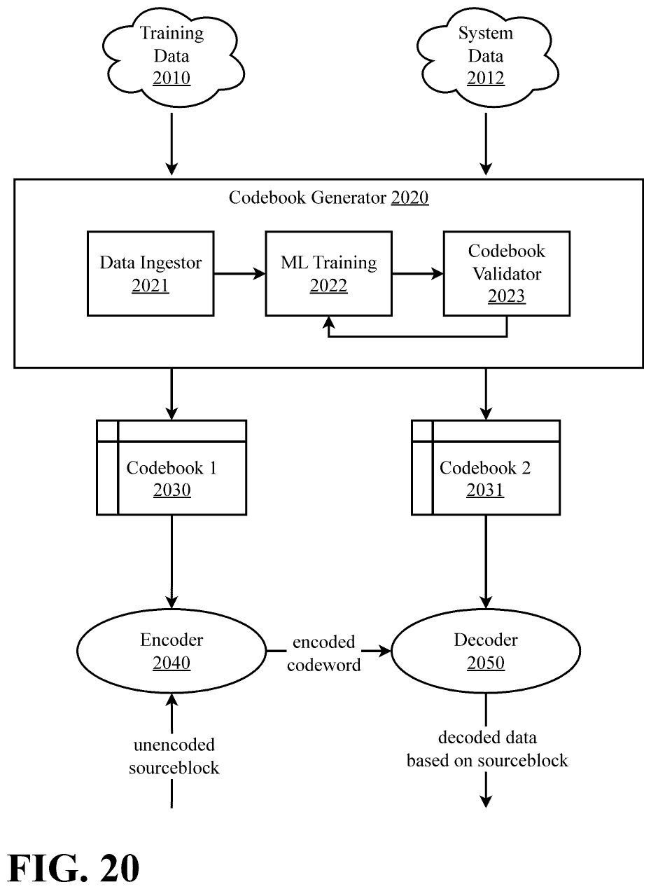

FIG. 20 is a block diagram illustrating an exemplary system architecture for data compression and decompression using asymmetric codebooks. In this configuration, additional system data 2012 such as (for example, including but not limited to) system hardware information, data files, environmental context such as date/time/location, or other data may be combined with training data 2010 fed into a codebook generator 2020. The codebook generator 2020 uses a machine learning (ML) subsystem comprising a data ingestor 2021 that receives and preprocesses incoming training and system data (for example, normalizing data into a consistent format and discarding undesirable data values to avoid degrading a ML model). The preprocessed data is used in ML training 2022 to develop a model that can generate useful codebooks based on the input data. A codebook validator 2023 then verifies the function of a generated codebook, which may in turn be fed back into a training loop 2022 for use as additional input to refine the model by retraining on known-good outputs.

A first validated codebook 2030 is sent to the encoder 2040 which receives unencoded sourceblocks, encodes them into codewords using the codebook 2030, and sends encoded data in the form of codewords to the decoder 2050. The decoder 2050 is given a second, different codebook 2032 and receives the encoded data in the form of codewords, decodes it using the second codebook 2030 (thus effecting an asymmetric encoding/decoding arrangements using different codebooks), but instead of outputting decoded data which is identical to the unencoded data received by the encoder 2040, the codebook asymmetry results in the decoding operation producing different data that is merely based on the original sourceblock. The ML process that generated the separate codebooks may be used to determine what sort of decoded data is produced through training of the model used, for example to create a codebook that produces specifically-transformed data from received codewords in order to effect data obfuscation or encryption, or to produce new useful data without revealing (to the decoder) the original content that was used to generate the codewords-an effect similar to producing hashes of input data so that useful output data may be produced while the source data remains concealed from the decoder.

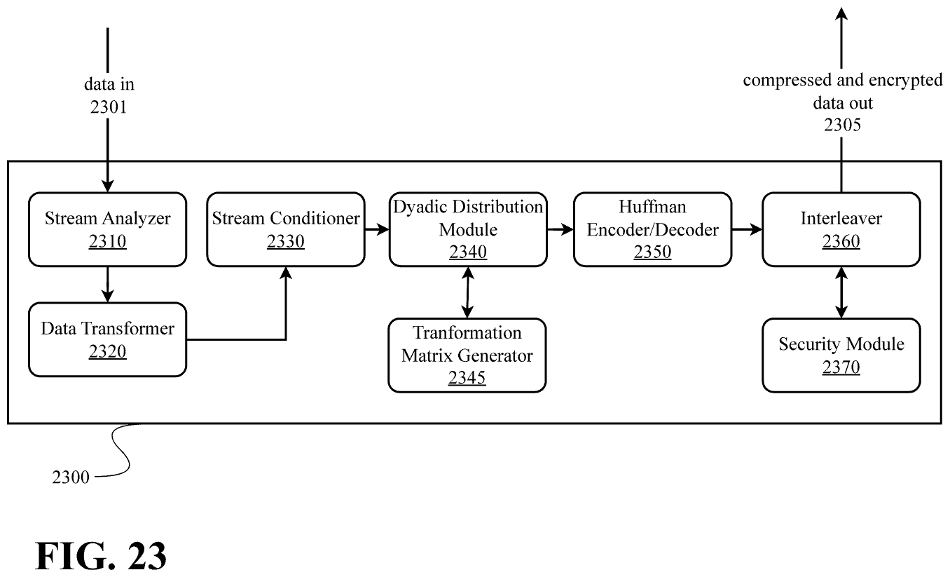

FIG. 23 is a block diagram illustrating an exemplary system architecture for a dyadic distribution-based compression and encryption platform 2300, according to an embodiment.

According to the embodiment, the platform 2300 comprises a stream analyzer 2310 which receives, retrieves, or otherwise obtains an input data stream 2301, a data transformer 2320, a stream conditioner 2330, an dyadic distribution algorithm subsystem module 2340 which integrates with a transformation matrix generator 2345, one or more Huffman encoder/decoders 2350, an interleaver 2360 which interfaces with a security subsystem module 2370 and which outputs a compressed and encrypted data stream 2305. In this exemplary architecture, data flows as illustrated. Stream analyzer 2310 first processes the input data 2301, passing its analysis to data transformer 2320. The stream conditioner 2330 then further processes the data before it's passed to dyadic distribution module 2340. The dyadic distribution module/subsystem 2340 works in conjunction with transformation matrix generator 2345 to apply the necessary transformations and generate a secondary transformation data stream. The Huffman encoder/decoder 2350 compresses the data into a compressed input data stream, which is then interleaved with the secondary transformation data stream by interleaver 2360. The security module 2370 interacts with interleaver 2360 to ensure the cryptographic properties of the output stream are maintained. This architecture allows for a modular implementation where each component can be optimized or replaced independently, while still maintaining the overall flow and functionality of the system.

In some implementations, platform 2300 may be implemented as a cloud-based service or system which hosts and/or supports various microservices or subsystems (e.g., components 2310-2370 implemented as microservices/subsystems). In some implementations, platform 2300 may be implemented as computing device comprising a memory and a processor, with computer readable programming instructions (or other computer-readable storage media) stored within the memory and operable/executable by/on the processor which cause the computing device to perform various operations associated with the execution of one or more platform tasks described herein.

According to the embodiment, stream analyzer 2310 is present and configured to analyze an input data stream to determine it statistical properties. This may comprise performing frequency analysis on data blocks within the input stream. It can determine the most frequent bytes or strings of bytes that occur at the beginning of each data block and designates these as prefixes. It may compile a prefix table based on the frequency distribution.

According to the embodiment, data transformer 2320 is present and configured to apply one or more transformations to the data to make it more compressible and secure. In an implementation, the platform applies the Burrows-Wheeler Transform (BWT) to the prefixes in the prefix table. This transformation makes the data more compressible while also providing a layer of encryption.

According to the embodiment, stream conditioner 2330 is present and configured to produce a conditioned data stream and an error stream. For example, for each data block, it compares the block's real frequency against an ideal frequency. If the difference exceeds a threshold, it applies a conditioning rule. It then applies a logical XOR operation and append the output to an error stream.

The dyadic distribution module 2340 receives the data stream and implements the core algorithm. This may comprise transforming the input data into a dyadic distribution whose Huffman encoding is close to uniform. It stores the transformations in a compressed secondary stream which may be (selectively) interwoven with the first, currently processing input stream.

Dyadic distribution module 2340 may integrate with transformation matrix generator 2345. The transformation matrix generator creates and manages the transformation matrix B. According to an aspect, the generator constructs a nonnegative, row-stochastic matrix where each entry represents the probability of transforming one state to another as an instance of matrix B. The matrix is configured to ensure that the transformation reshapes the data distribution while introducing controlled randomness.

According to an implementation, transformation matrix generator 2345 creates the transformation matrix B based on the initial analysis of the input data distribution provided by the stream analyzer. This matrix B is a component that dyadic distribution module 2340 will use throughout the process. As the dyadic distribution module receives each data block, it consults the transformation matrix B to determine how to transform the data. For each state (or symbol) in the input data, the data transformer uses the corresponding row in matrix B to determine the probability distribution for transforming that state to other states. The dyadic distribution module may use a random number generator (such as provided by security module 2370) to select a transformation based on the probabilities in matrix B. This introduces controlled randomness into the process.

Through these transformations, the dyadic distribution module reshapes the data distribution to approach the dyadic distribution implied by the Huffman coding (as determined by the Huffman encoder/decoder). As transformations are applied, dyadic distribution module 2340 provides feedback to transformation matrix generator 2345 about the actual transformations performed. This allows the transformation matrix generator to refine matrix B if necessary. According to an embodiment, if the input data distribution changes over time, the transformation matrix generator can adapt matrix B based on new information from the stream analyzer. The dyadic distribution module will then use this updated matrix for subsequent transformations. The dyadic distribution module keeps track of the transformations it applies and generates a secondary data stream containing this information. This “transformation data” is important for the decoding process and may be interleaved with the main data stream by interleaver 2360. The transformation matrix generator continually works to optimize matrix B to minimize the amount of transformation data needed while maintaining the desired dyadic distribution.

Both transformation components (dyadic distribution module and matrix generator) work together to ensure that the transformations contribute to the cryptographic security of the system. The transformation matrix generator designs matrix B to make prediction of future states difficult, while the dyadic distribution module applies these transformations in a way that passes the modified next-bit test. In essence, the dyadic distribution module and transformation matrix generator form a tight feedback loop. The transformation matrix generator provides the rules for transformation (in the form of matrix B), while the dyadic distribution module applies these rules to the actual data. The results of these transformations then inform potential updates to the transformation rules, allowing the system to maintain optimal compression and security as it processes the data stream. This close interaction allows the system to dynamically balance compression efficiency and cryptographic security, adapting to changes in the input data characteristics while maintaining the core properties that make the dyadic distribution algorithm effective.

The input data then flows into a Huffman encoder/decoder 2350 which is configured to perform Huffman coding for compression and decoding for decompression. This may comprise constructing a Huffman tree based on the probability distribution of the input data, and assigning shorter codewords to more frequent symbols for compression. For decompression, it reverses the process.

According to the embodiment, interleaver 2360 is present and configured to interleave the compressed and encrypted data streams. This may comprise combining the main data stream (e.g., the input data stream that has been processed by one or more platform components) with the secondary “transformation data” stream according to a specific partitioning scheme to create the final output. This scheme is designed to maximize security while maintaining efficient compression. Interleaver 2360 may integrate with security module 2370 during data processing. In an embodiment, security module implements security features such as the modified next-bit test. For example, the interleaver works with the security module to determine how many bits from each stream should be included in each block of the output. This allocation may be dynamic and based on security requirements and the current state of the data. In some implementations, before interleaving, the security module encrypts the transformation data using a cryptographic algorithm. This adds an extra layer of security to the sensitive information about how the data was transformed. In some implementations, the security module provides cryptographically secure random numbers to the interleaver (or other platform components such as dyadic distribution module). These may be used to introduce controlled randomness into the interleaving process, making it harder for an adversary to separate the two streams.

As the interleaver combines the streams, the security module performs ongoing checks to ensure the resulting stream maintains the required cryptographic properties, such as passing the modified next-bit test. According to an aspect, security module 2370 monitors the entropy of the interleaved stream. If the entropy drops below a certain threshold, it signals the interleaver to adjust its strategy, possibly by including more bits from the transformation data stream. In embodiments where the system uses cryptographic keys (e.g., for encrypting the transformation data), the security module manages these keys and provides them to the interleaver as needed. According to an aspect, based on feedback from the security module about the cryptographic strength of recent output, interleaver 2360 may adaptively change its interleaving strategy.

In an implementation, the security module advises the interleaver on how to maintain consistent timing in its operations to prevent timing-based attacks. This might involve adding deliberate delays or dummy operations. The interleaver may consult the security module on how to securely include any necessary headers or metadata in the output stream. This ensures that even auxiliary data doesn't compromise the system's security. According to an aspect, security module 2370 provides integrity check values (e.g., hash values or MAC codes) to interleaver 2360, which are then incorporated into the output stream. These allow the receiver to verify the integrity of the received data. According to another aspect, security module 2370 guides the interleaver in implementing techniques to resist side-channel attacks, such as ensuring that the power consumption or electromagnetic emissions during interleaving don't leak information about the data being processed.

In an implementation, if the interleaver encounters any issues during the interleaving process, it may consult the security module on how to handle these errors securely without leaking information about the underlying data or transformation process. In an implementation, the interleaver, guided by the security module, can include secure hints or markers in the output stream that will assist in the decoding process without compromising security. The interleaver and security module work in tandem to produce an output stream that is both compressed and securely encrypted. The interleaver focuses on efficiently combining the data streams, while the security module ensures that every step of this process maintains the cryptographic properties of the system. This close cooperation allows the platform to achieve its dual goals of data compression and encryption in a single, efficient process.

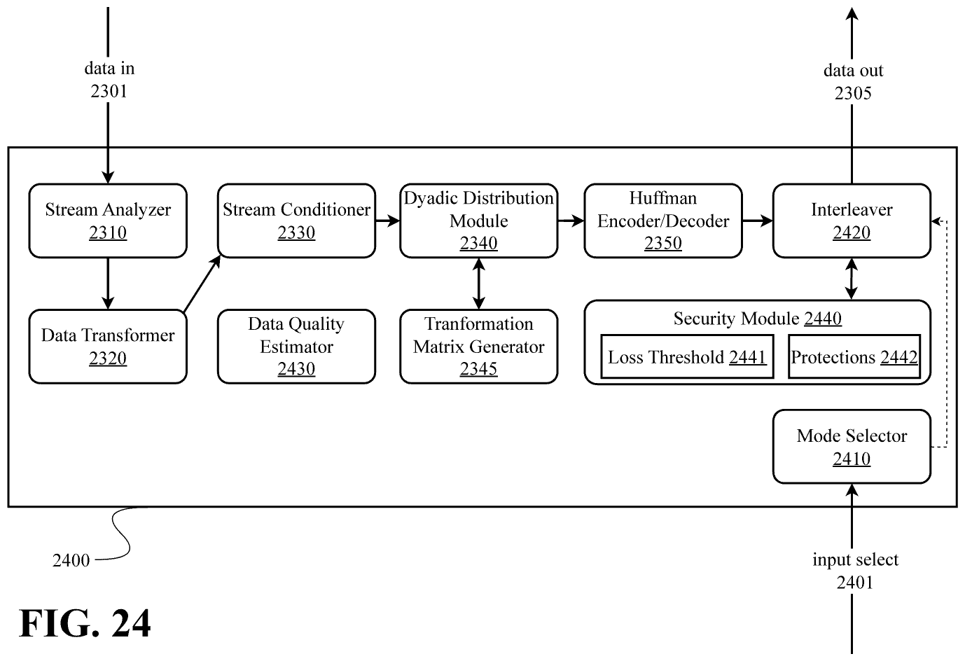

FIG. 24 is a block diagram illustrating another exemplary system architecture for a dyadic distribution-based compression and encryption platform 2400, according to an embodiment. According to an embodiment, a modification to the compression and encryption platform 2400 could be implemented as an optional mode within the existing platform architecture, allowing for flexibility in its application. For example, this may require the addition of a mode selector component 2410, which can determine whether to operate in the original lossless mode, the new lossy, high-security mode, in a modified lossless mode. Mode selector 2410 may receive input data 2401 which selects or otherwise sets the mode of operation of platform 2400. Input select data may be received from various sources such as, for example, a platform user (human or computer implemented agent), or an external application, service, or computing resource.

According to an embodiment, the platform may be modified to only send the modified stream without the secondary stream containing the modification information. This alteration fundamentally changes the nature of the compression from lossless to lossy, while simultaneously strengthening the encryption aspect of the system. The dyadic distribution module, guided by transformation matrix generator 2340, would still modify the input data to achieve a dyadic distribution. However, without the accompanying transformation data stream, perfect reconstruction of the original data becomes impossible, even with possession of the codebook used by Huffman encoder/decoder 2350.

Interleaver 2420 may receive from mode selector 2410 a signal and/or instruction (illustrated as the dotted line) on what process to apply to the one or more input data streams. If the platform is configured to perform the original lossless mode, interleaver 2420 interleaves the compressed input data stream and the secondary transformation data stream. If the platform is configured to perform lossy compression, interleaver 2420 does not interleave the two data streams, but instead transmits only the compressed input data stream. If the platform is configured to perform a modified lossless compression, interleaver 2420 can transmit the compressed input data stream by itself in a first transmission session, and then it may transmit the secondary transformation data stream by itself in a second transmission session. In some embodiments, the secondary transformation data stream may be encrypted according to a suitable data encryption technique prior to transmission. Encryption techniques that may be implemented can include, but are not limited to, advance encryption standard (AES), asymmetric encryption (e.g., RSA), symmetric encryption (e.g., Twofish), and/or the like.

Security module's 2440 role becomes even more critical in the implementation of lossy modified system. It ensures that the encrypted data stream maintains its cryptographic strength, potentially approaching perfect encryption. The absence of the secondary stream eliminates a potential attack vector, as the transformation information is never transmitted. Interleaver's 2420 function would be simplified, focusing solely on managing the primary data stream, but it would still work closely with the security module to maintain the stream's cryptographic properties.

This approach presents a compelling trade-off between data integrity and transmission efficiency coupled with enhanced security. The stream analyzer's role remains the same in analyzing the input data characteristics, allowing the platform to optimize the compression and transformation processes. The loss of data introduced by this method is directly related to the transformations applied by the data transformer, guided by the transformation matrix generator.

Potential applications for this modified system include scenarios where perfect data reconstruction is not critical, but high compression ratios and stringent security requirements are paramount. Examples may include certain types of media streaming, sensor data transmission in IoT environments, or secure transmission of non-critical telemetry data.

According to an embodiment, to address concerns about data integrity, platform 2400 may incorporate a configurable loss threshold 2441 managed by security module 2440. This threshold can allow users to set a maximum acceptable level of data loss. If the estimated loss exceeds this threshold, the platform could automatically revert to the lossless mode or alert the user.

Additionally, the platform may be extended to include a data quality estimator component 2430. This component may work in conjunction with various components (e.g., stream analyzer, data transformer, dyadic distribution module) to provide real-time estimates of the quality of the compressed and encrypted data compared to the original. This could be particularly useful in applications like media streaming, where maintaining a certain level of perceptual quality is crucial.

Finally, it's worth noting that the lossy, high-security mode could potentially offer resistance to certain types of side-channel attacks, as the lack of perfect reconstruction could mask some of the subtle correlations that these attacks often exploit. In an embodiment, security module 2440 can be expanded to include specific protections 2442 against such attacks, further enhancing the overall security profile of the system. These protections would aim to mitigate various types of side-channel vulnerabilities that could potentially leak information about the encryption process or the data being processed. For example, some specific protections that may be implemented can include, but are not limited to, timing attack mitigation, power analysis countermeasures, electromagnetic emission protection, cache attack prevention, branch prediction attack mitigation, fault injection resistance, memory access patter obfuscation, randomization techniques, microarchitectural attack mitigations, side-channel resistant algorithms, runtime monitoring, and adaptive countermeasures.

### Description of Method Aspects

The methods and processes described herein are illustrative examples and should not be construed as limiting the scope or applicability of the cross-stream asymmetric enhancement platform. These exemplary implementations serve to demonstrate the versatility and adaptability of the platform. It is important to note that the described methods may be executed with varying numbers of steps, potentially including additional steps not explicitly outlined or omitting certain described steps, while still maintaining core functionality. The modular and flexible nature of the cross-stream asymmetric enhancement platform allows for numerous alternative implementations and variations tailored to specific use cases or technological environments. As the field evolves, it is anticipated that novel methods and applications will emerge, leveraging the fundamental principles and components of the platform in innovative ways. Therefore, the examples provided should be viewed as a foundation upon which further innovations can be built, rather than an exhaustive representation of the platform's capabilities.

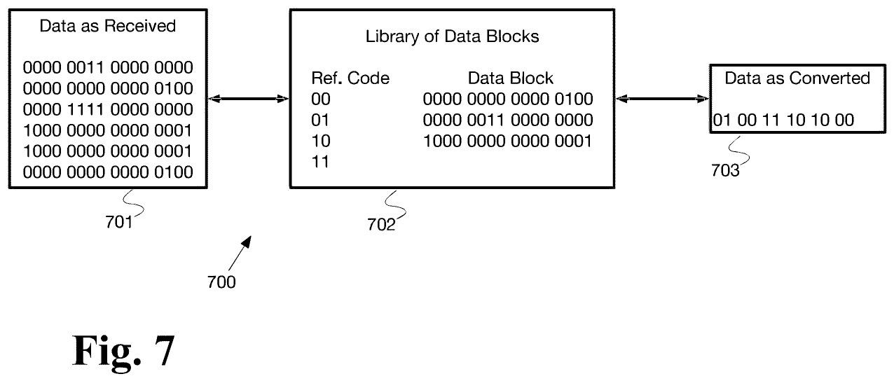

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11is initially empty. As each 16 bit sourceblock is received, it is compared with the library. If that sourceblock is already contained in the library, it is assigned the corresponding reference code.

So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

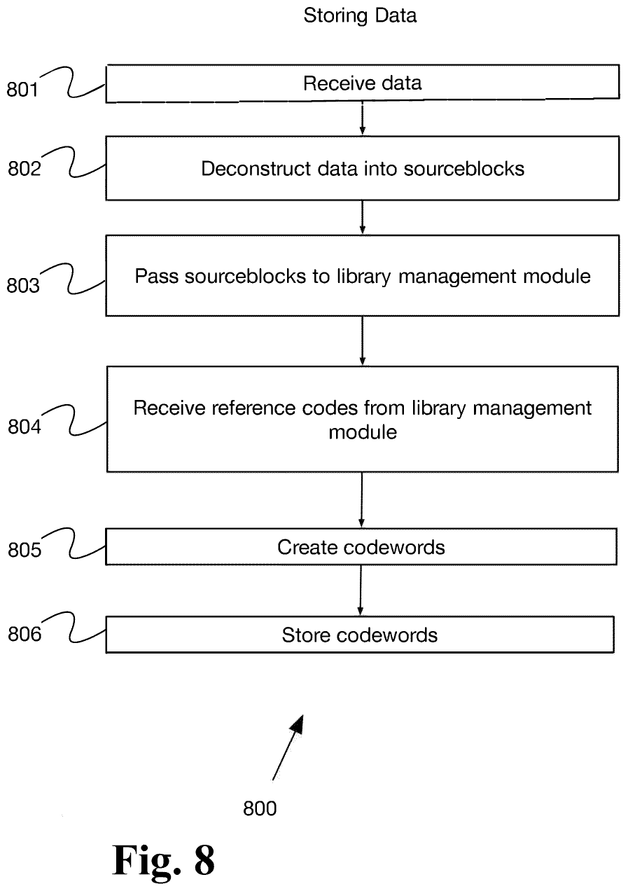

FIG. 8 is a method diagram showing the steps involved in using an embodiment 800 to store data. As data is received 801, it would be deconstructed into sourceblocks 802, and passed 803 to the library management module for processing. Reference codes would be received back 804 from the library management module, and could be combined with location information to create codewords 805, which would then be stored 806 as representations of the original data.

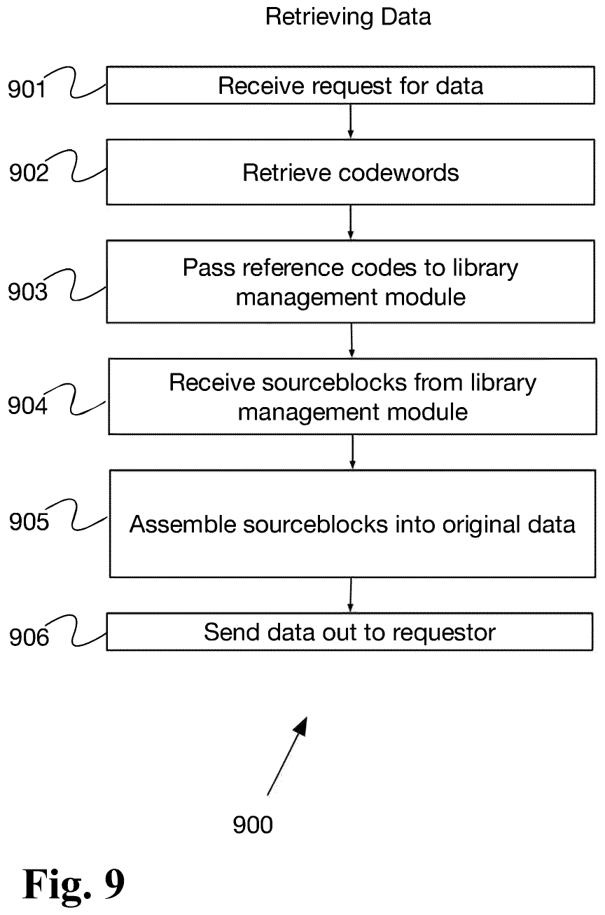

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

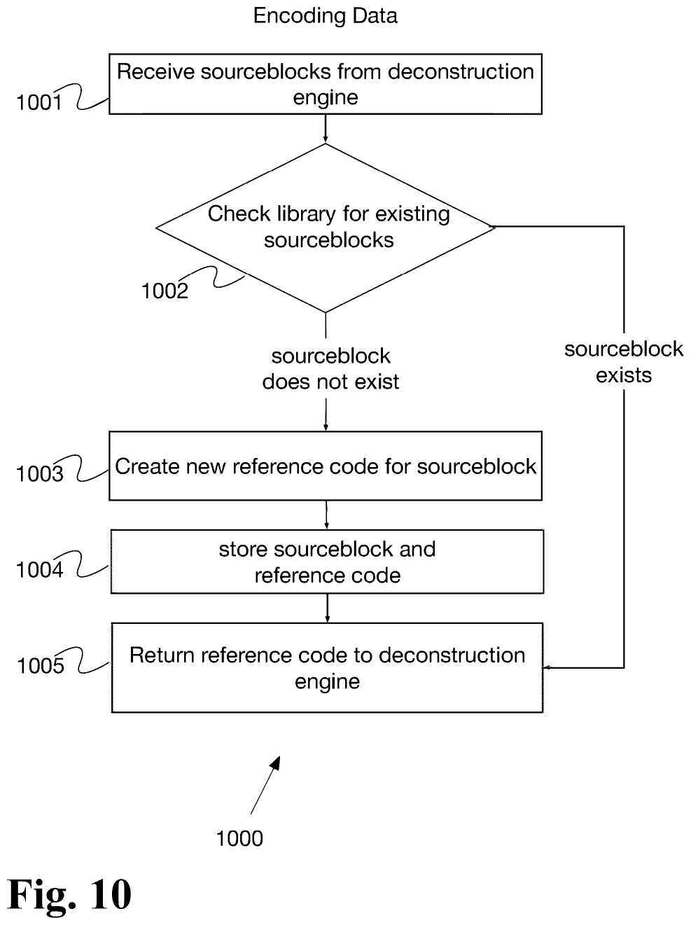

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

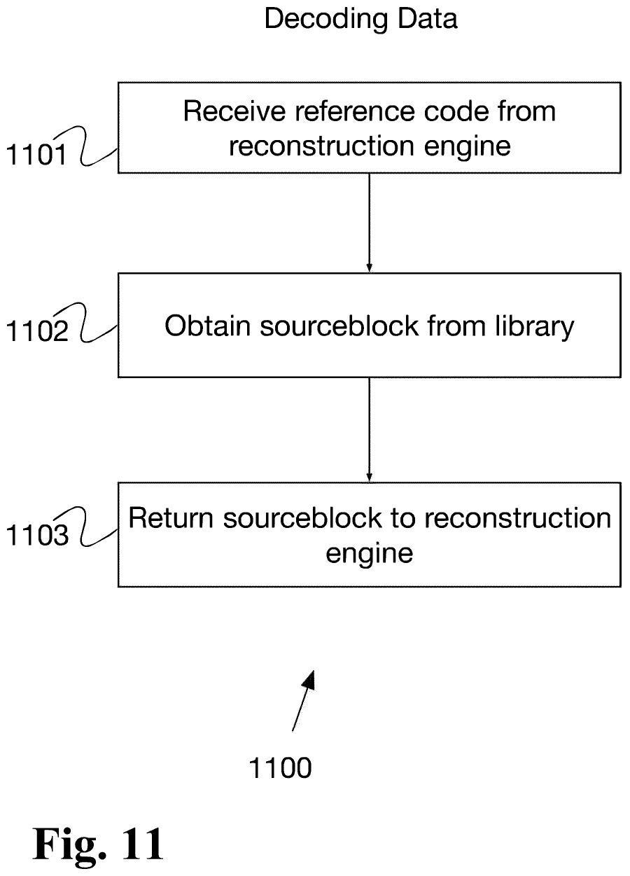

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

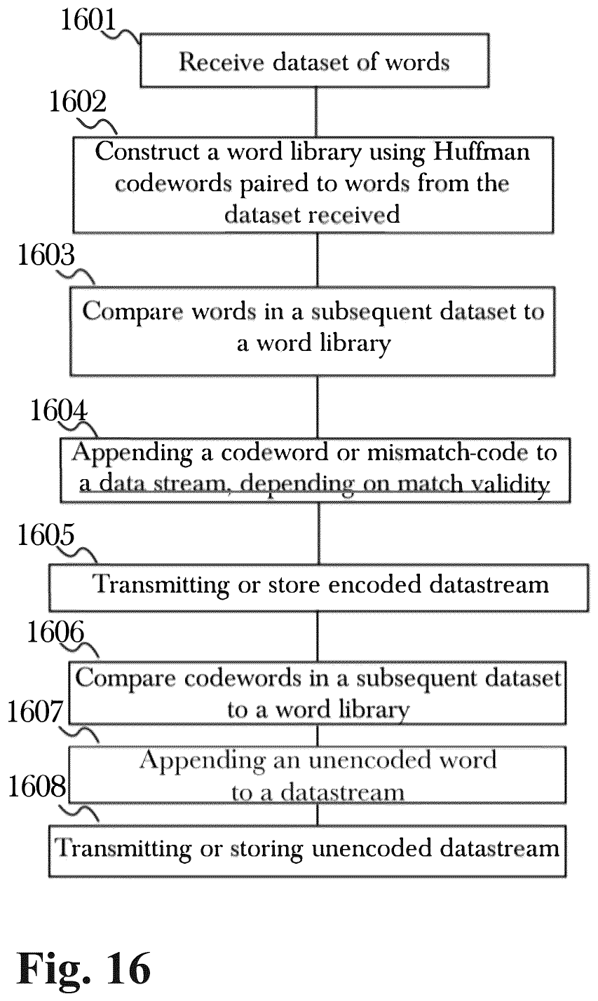

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received, and compared to the word library 1603 to determine the proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

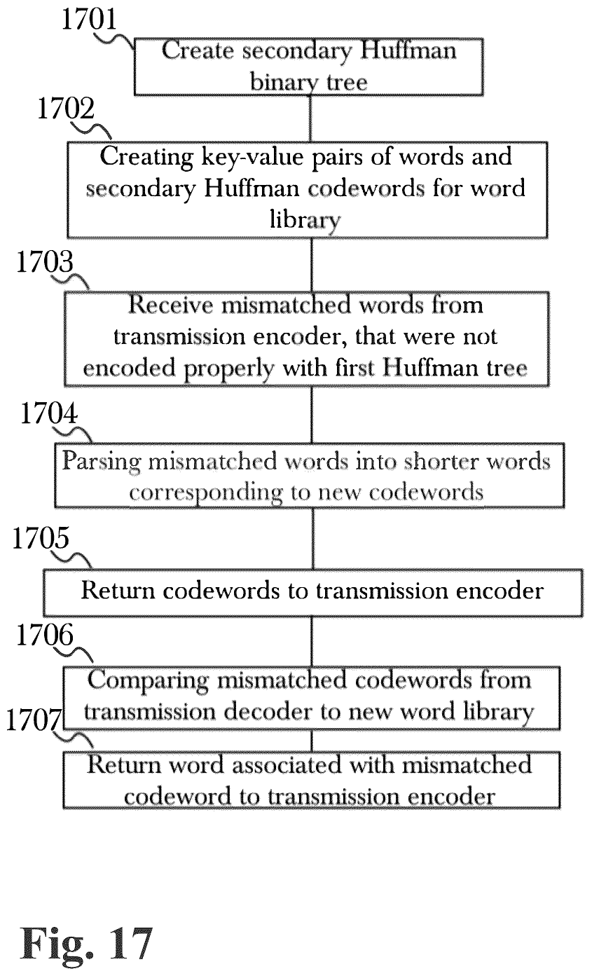

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

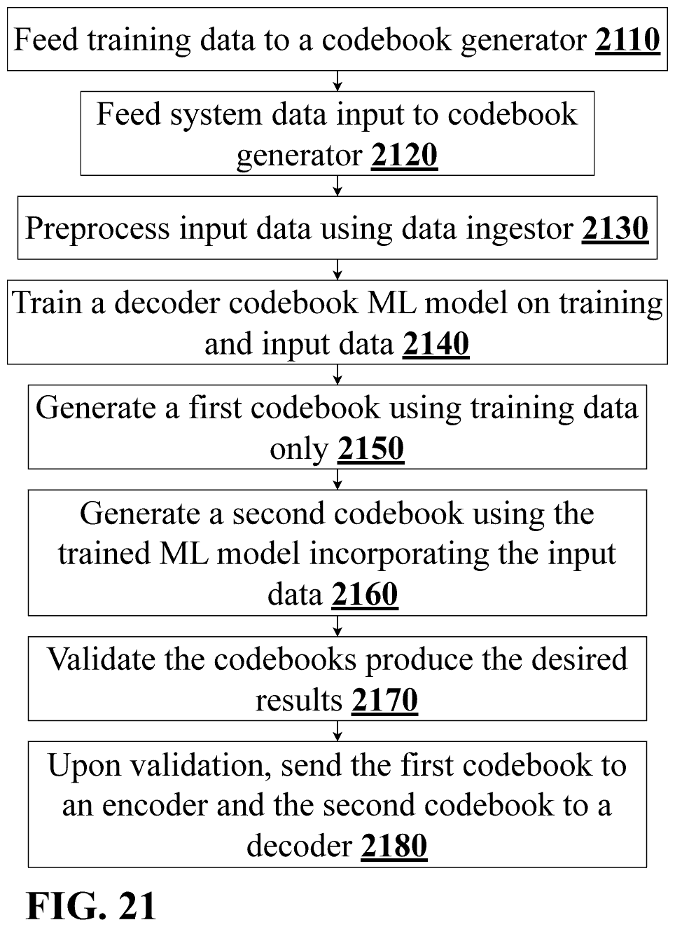

FIG. 21 is a flow diagram illustrating an exemplary method for generating and distributing asymmetric codebooks. According to this method, training data may be provided to a codebook generator 2110 along with additional input data 2120 for use in training a ML model for generating asymmetric codebooks according to a desired encoding/decoding result. For example, a model may be trained to produce a decoder codebook such that specifically-transformed data is produced by a decoding operation, rather than producing the original sourceblocks that were encoded. The input data may be preprocessed 2130 by a data ingestor 2021, for example to normalize input values and discard unnecessary data to train the model more efficiently. ML models may then be trained on the training data and normalized input values 2140, to produce a model configured to generate codebooks for the desired purpose. A first codebook may be generated with a model trained on only the training data (without the additional input data) 2150, to produce a first codebook for use at an encoder. A second codebook may be generated using the trained model incorporating the additional input data 2160, producing a second codebook for use at a decoder, that differs from the first. For example, a second codebook may be generated for the purpose of producing obfuscated output data based on the decoded codewords, rather than reproducing the original sourceblocks that were encoded. Through training of the ML model, this obfuscated output data may be tailored for a particular purpose such as encryption or transformation of the original data, according to a desired use case. A codebook validator may be used to check that the generated codebooks produce the desired results, thereby confirming the validity of the trained models used 2170, and upon successful validation the first codebook (that is, a codebook generated without the additional input data) may be provided to an encoder, and the second codebook (based on the ML model trained on the additional input data) may be provided to a decoder 2180, completing the asymmetric codebook configuration.

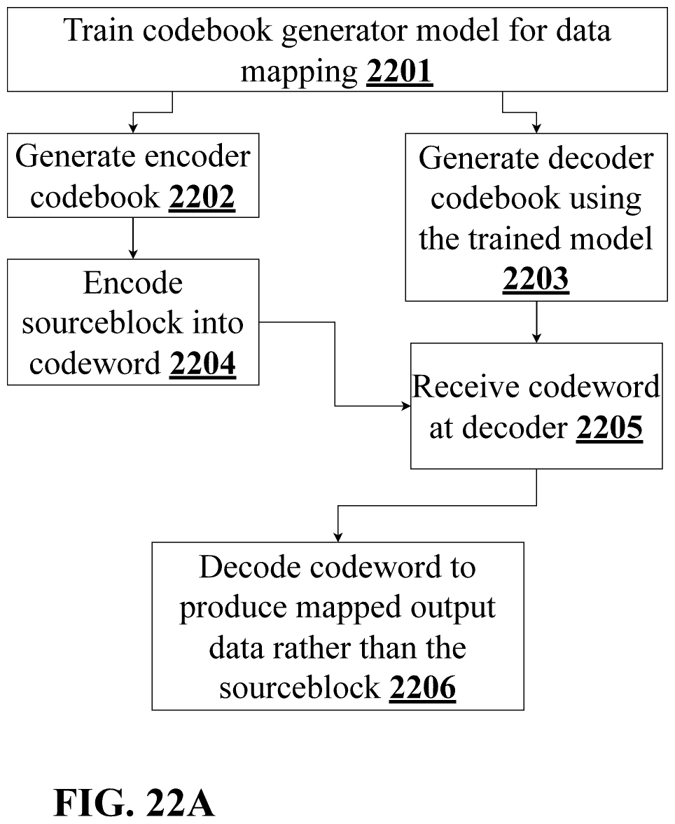

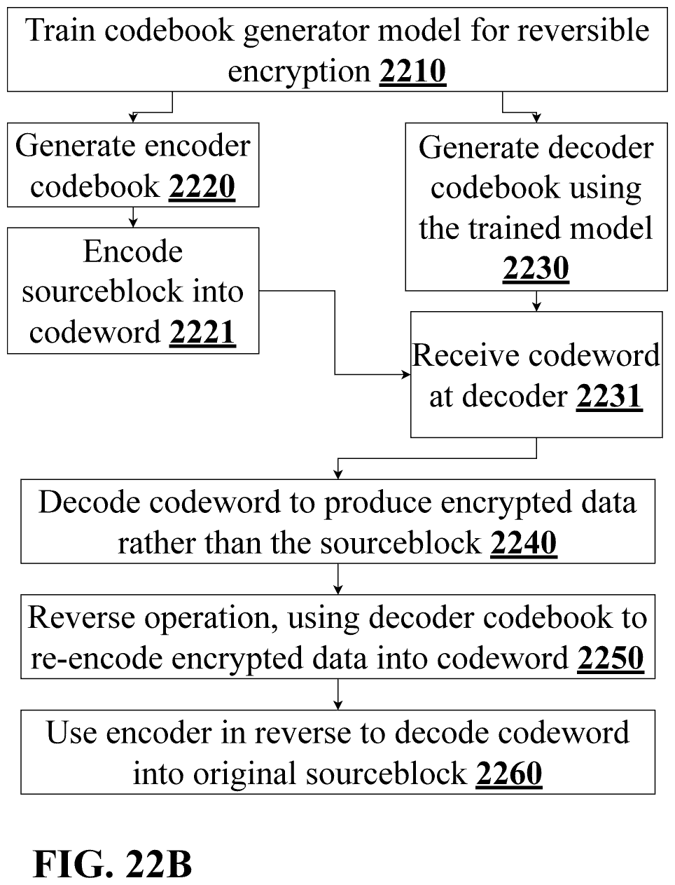

FIG. 22A is a flow diagram illustrating an exemplary method for using asymmetric codebooks to provide data mapping at a reconstruction engine. According to this method, asymmetric codebooks may be used to map data at a decoder without the need for a data mapping and transformation appendix. This facilitates data transformations as an inherent function of the encoder/decoder codebooks themselves, streamlining operation. First, a codebook generator trains an ML model for the purpose of data mapping 2201, as described above in FIG. 21. A first encoder codebook is then generated 2202 and provided to a data encoder, while a second asymmetric codebook is generated 2203 using the trained model and provided to a decoder. A sourceblock is then encoded at the encoder 2204 using the first codebook, and sent to the decoder where it is received 2205 and decoded. However, rather than decoding the codeword and restoring the original sourceblock, the asymmetric codebook results in producing mapped data as output 2206 that is merely based on the original sourceblock, without revealing the sourceblock itself to the decoder. This results in output similar to a hashing operation, wherein a given sourceblock consistently results in the same codeword (at the encoder, using the first codebook), and a given codeword consistently results in the same output data (at the decoder, using the second codebook), but there is no direct correlation that the decoder can use to infer the original sourceblock. In this way, the output data may be used in place of the sourceblock (similar to using a hashed password, for example) without knowing the original sourceblock data; using a hashed password as an analog, a server might use a hashed password for user authentication without any knowledge of the user's actual password. This provides added data security for various use cases while streamlining the data transformation process and making it an implicit function of the encoding and decoding process.

FIG. 22B is a flow diagram illustrating an exemplary method for using asymmetric codebooks to facilitate data encryption. According to this method, asymmetric codebooks may be used in a bidirectional manner in which the encoder and decoder can each perform both encoding and decoding processes by simply reversing the order of operations using their respective codebooks. First, a codebook generator trains an ML model for the purpose of reversible data encryption 2210, as described above in FIG. 21. A first encoder codebook is then generated 2220 and provided to a data encoder, while a second asymmetric codebook is generated 2230 using the trained model and provided to a decoder. A sourceblock is then encoded at the encoder 2221 using the first codebook, and sent to the decoder where it is received 2231 and decoded. However, rather than decoding the codeword and restoring the original sourceblock, the asymmetric codebook results in producing encrypted data as output rather than decoding the codeword to recover the original sourceblock. This encrypted data may then be decrypted through a reverse process: the decoder uses its codebook to re-encode the encrypted data and produce the original codeword 2250, which is sent to the encoder to then use its respective codebook to decode the codeword and restore the original sourceblock 2260. In this manner, asymmetric codebooks may be employed to provide a reversible data encryption operation that never exposes the original (sourceblock) data to the decoder or any entity using the codewords or decoded encrypted output data. When decryption is necessary, the asymmetric codebooks are applied in reverse order, resulting in the restoration of the original sourceblock information.

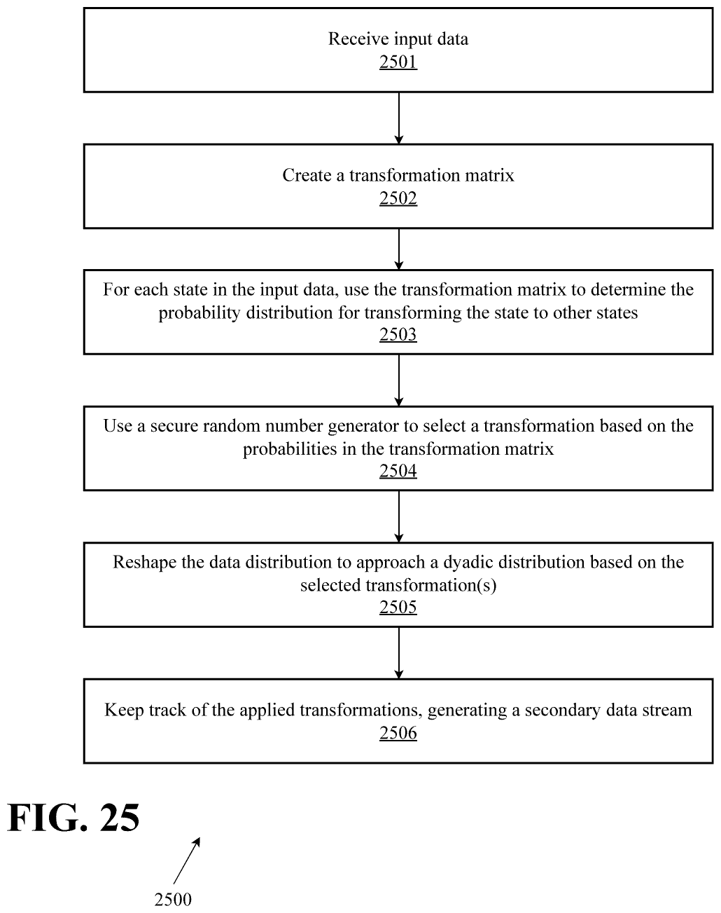

FIG. 25 is a flow diagram illustrating an exemplary method 2500 for implementing a dyadic distribution algorithm, according to an aspect. The method may be performed, in whole or in part, by one or more dyadic distribution-based compression and encryption platforms. According to the aspect, the process begins at step 2501 when dyadic distribution module 2340 receives input data. The input data may have been previously analyzed and processed by other platform components (e.g., stream analyzer, data transformer). At step 2502, the platform creates a transformation matrix using a transformation matrix generator 2345. The transformation matrix may be referred to herein as matrix B. At step 2503, for each state in the input data, module 2340 consults matrix B to determine the probability distribution for transforming that state to other states. According to the aspect, at step 2504 the platform uses a secure random number generator to select a transformation based on the probabilities in the transformation matrix. At step 2505, the platform reshapes the data distribution to approach the dyadic distribution of Huffman encoding based on the selected transformations. At step 2506, the platform keeps track of the applied transformations and generates a secondary data stream.

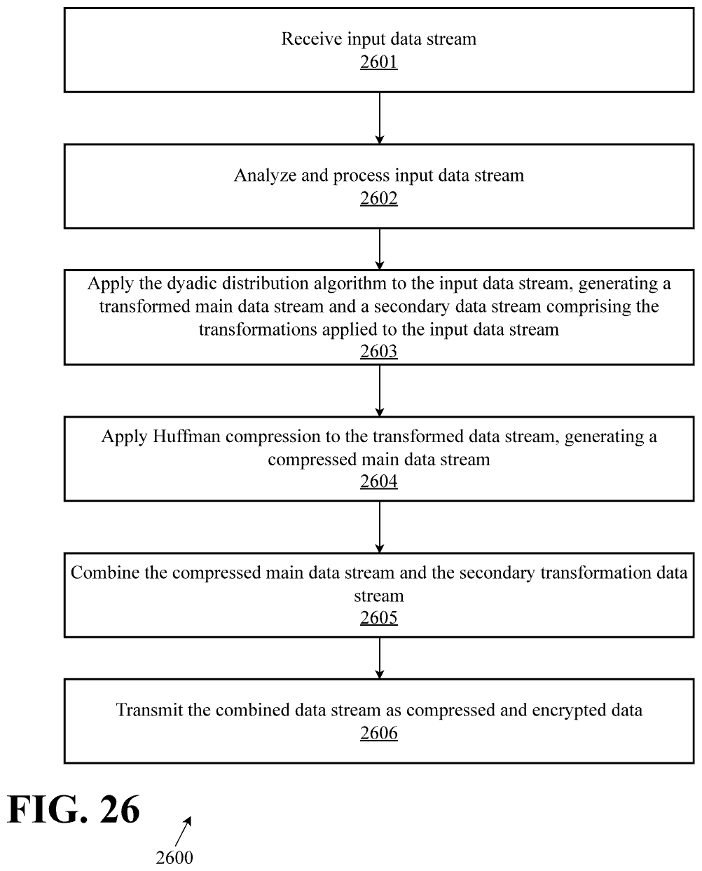

FIG. 26 is a flow diagram illustrating an exemplary method 2600 for providing lossless, dyadic distribution-based compression and encryption, according to an aspect. According to the aspect, the process begins at step 2601 when platform 2300, 2400, receives, retrieves, or otherwise obtains an input data stream. At step 2602, the platform analyzes and processes the input data stream. This may comprise frequency analysis as performed by a stream analyzer subsystem and processing performed by a data transformer and/or a stream conditioner. At step 2603, the platform applies the dyadic distribution algorithm to the input data stream (which may have been processed at step 2602), generating a transformed main data stream and a secondary data stream comprising the transformations applied to the input data stream. The secondary data stream may be sent to an interleaver subsystem for transmission. At step 2604, the platform applies Huffman compression to the transformed main data stream, generating a compressed main data stream. The interleaver can obtain both data streams and combine them into an interleaved data stream at step 2605. At step 2606, the platform transmits the combined data stream as a compressed and encrypted data stream. The transmitted data may be received on the receiving end with a platform configured with an Huffman decoder which can decompress the received main data stream using the attached secondary stream and the proper codebook.

### Hardware Architecture

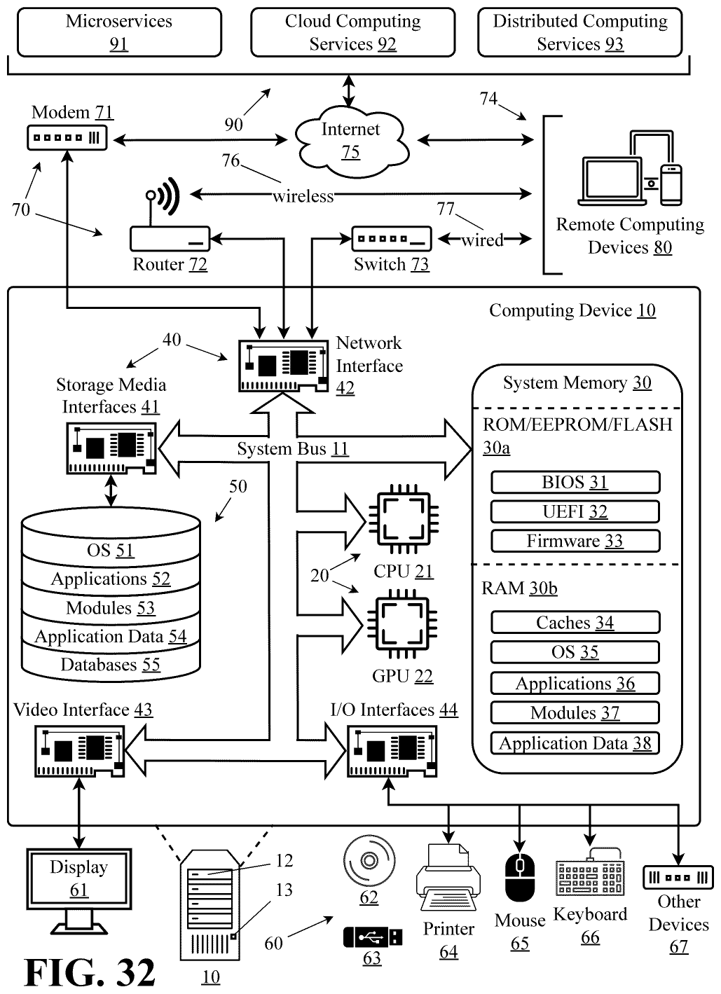

FIG. 32 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry

Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as contained.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 arc shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A system for cross-stream asymmetric enhancement with multi-objective optimization, comprising:
a computing device comprising a processor and a memory;
a plurality of programming instructions stored in the memory which, when operating on the processor, cause the computing device to:
analyze input data to determine processing requirements for multiple objectives comprising compression efficiency, cryptographic security, and error correction capability;
generate a plurality of asymmetric codebooks using machine learning algorithms, wherein each asymmetric codebook is optimized for a different objective and produces different output transformations when applied to the same input data;
apply dyadic distribution processing to the input data to create multiple data streams, wherein each data stream is pre-conditioned for optimal processing by a corresponding asymmetric codebook;
process the multiple data streams using the plurality of asymmetric codebooks to simultaneously optimize the multiple objectives; and
generate output data according to a selected combination of the processed data streams, wherein different stream combinations provide different levels of reconstruction capability.

2. The system of claim 1, wherein the plurality of asymmetric codebooks comprises a compression-optimized codebook that maximizes data reduction, a security-optimized codebook that maximizes cryptographic strength, and an error-correction-optimized codebook that maximizes error detection and correction capability.

3. The system of claim 1, wherein the dyadic distribution processing transforms probability distributions of the input data to optimize compatibility with subsequent asymmetric codebook processing.

4. The system of claim 1, wherein the machine learning algorithms comprise neural networks trained using multi-objective optimization techniques that balance competing performance criteria across the multiple objectives.

5. The system of claim 1, wherein the selected combination of processed data streams comprises an ultra-high compression mode using a single stream, a broadcast quality mode using two streams, or an archival mode using three streams.

6. The system of claim 1, wherein the plurality of programming instructions further cause the computing device to monitor performance metrics from the processed data streams and adaptively update the plurality of asymmetric codebooks based on the performance metrics.

7. The system of claim 1, wherein each asymmetric codebook comprises transformation matrices that are mathematically optimized for its corresponding objective while maintaining reconstruction capability for authorized users.

8. The system of claim 1, wherein the plurality of programming instructions further cause the computing device to coordinate processing across the multiple data streams to ensure that optimization of one objective does not compromise performance of other objectives.

9. The system of claim 1, wherein the different levels of reconstruction capability enable graduated access control where different users can access different quality levels of reconstructed data based on available stream combinations.

10. The system of claim 1, wherein the plurality of programming instructions further cause the computing device to apply additional security measures comprising stream interleaving and temporal encryption to the output data.

11. A method for cross-stream asymmetric enhancement with multi-objective optimization, comprising the steps of:
analyzing input data to determine processing requirements for multiple objectives comprising compression efficiency, cryptographic security, and error correction capability;
generating a plurality of asymmetric codebooks using machine learning algorithms, wherein each asymmetric codebook is optimized for a different objective and produces different output transformations when applied to the same input data;
applying dyadic distribution processing to the input data to create multiple data streams, wherein each data stream is pre-conditioned for optimal processing by a corresponding asymmetric codebook;
processing the multiple data streams using the plurality of asymmetric codebooks to simultaneously optimize the multiple objectives; and
generating output data according to a selected combination of the processed data streams, wherein different stream combinations provide different levels of reconstruction capability.

12. The method of claim 11, wherein generating the plurality of asymmetric codebooks comprises generating a compression-optimized codebook that maximizes data reduction, a security-optimized codebook that maximizes cryptographic strength, and an error-correction-optimized codebook that maximizes error detection and correction capability.

13. The method of claim 11, wherein applying dyadic distribution processing comprises transforming probability distributions of the input data to optimize compatibility with subsequent asymmetric codebook processing.

14. The method of claim 11, wherein the machine learning algorithms comprise neural networks trained using multi-objective optimization techniques that balance competing performance criteria across the multiple objectives.

15. The method of claim 11, wherein generating output data comprises selecting an ultra-high compression mode using a single stream, a broadcast quality mode using two streams, or an archival mode using three streams.

16. The method of claim 11, further comprising the steps of monitoring performance metrics from the processed data streams and adaptively updating the plurality of asymmetric codebooks based on the performance metrics.

17. The method of claim 11, wherein each asymmetric codebook comprises transformation matrices that are mathematically optimized for its corresponding objective while maintaining reconstruction capability for authorized users.

18. The method of claim 11, further comprising the step of coordinating processing across the multiple data streams to ensure that optimization of one objective does not compromise performance of other objectives.

19. The method of claim 11, wherein the different levels of reconstruction capability enable graduated access control where different users can access different quality levels of reconstructed data based on available stream combinations.

20. The method of claim 11, further comprising the step of applying additional security measures comprising stream interleaving and temporal encryption to the output data.
